(19) United States
(12) Patent Application Publication
(10) Pub. No.: US 2009/0133741 A1
(43) Pub. Date: May 28, 2009

(54) Photoelectric Conversion Device and Method of Manufacturing the Same, and Photoelectric Power Generation Device

(75) Inventors: Hisashi Higuchi, Higashiomi-shi (JP); Yuji Kishida, Soraku-gun (JP); Rui Kamada, Higashiomi-shi (JP)

Correspondence Address: HOGAN & HARTSON L.L.P., 1999 AVENUE OF THE STARS, SUITE 1400, LOS ANGELES, CA, 90067, US

(73) Assignee: KYOCERA CORPORATION, Kyoto-shi, Kyoto (JP)

(21) Appl. No.: 12/065,486

(22) PCT Filed: Sep. 4, 2006
(86) PCT No.: PCT/JP2006/317468

§ 371 Date: Nov. 19, 2008

(30) Foreign Application Priority Data
Sep. 2, 2005 (JP) 2005-254762
Sep. 5, 2005 (JP) 2005-256170
Apr. 6, 2006 (JP) 2006-105429

(51) Int. Cl. H01L 31/04; H01L 31/02

(52) U.S. Cl. 136/252; 438/73; 257/E31.11

(57) ABSTRACT

A photoelectric conversion device 1 comprises a laminated body comprising a conducting substrate 2, and an opposing electrode layer 3, a porous spacer layer 5 containing an electrolyte 4, a porous semiconductor layer 7 that adsorbs a dye 6 and contains the electrolyte 4 and a light-transmitting conductive layer 8 respectively laminated in this order on the conducting substrate 2. Consequently, the thickness of the electrolyte layer determined previously by a gap between two substrates is allowed to be determined according to the thickness of a spacer layer containing an electrolyte 4, and thus the electrolyte layer can be made both thin and uniform, and the conversion efficiency and reliability can be improved.

### TECHNICAL FIELD

The present invention relates to a photoelectric conversion device such as a photovoltaic cell and a photo diode with excellent photoelectric conversion efficiency and reliability, and a method of manufacturing the same.

### BACKGROUND ART

In prior art, a dye-sensitized solar cell that is a type of photoelectric conversion device does not require a vacuum apparatus during manufacturing and thus is considered to have a low environment load at low cost, and research and development are therefore performed actively.

This dye-sensitized solar cell normally comprises a porous titanium oxide layer with a thickness of about 10 μm obtained by sintering fine particles of titanium oxide with a mean particle size of about 20 nm at about 450° C. on a conducting glass substrate. Then, a photosensitive electrode substrate formed by a photosensitive electrode layer wherein dyes are monomolecularly adsorbed on the surface of titanium oxide particles of the porous titanium oxide layer and an opposing electrode substrate comprising an opposing electrode layer of platinum or carbon on the conducting glass substrate are mutually opposed, and a frame-shaped thermoplastic resin sheet is used as spacer and sealing member, such that both substrates are sandwiched together by hot pressing. The composition then provides an electrolyte solution including iodine/iodide redox mediator that is injected and filled between these substrates through holes opened in the opposing electrode substrate, after which the holes of the opposing electrode substrate are closed (refer to Non-patent Document 1).

The surface area of a solar cell is large, and therefore when two large substrates (the photosensitive electrode substrate and the opposing electrode substrate) are attached together, in order to maintain a gap that satisfies the electrolytes, the insertion of various spacers has been previously investigated.

Regarding a dye-sensitized solar cell comprising an arrangement of an electrolyte layer between a dye-sensitization photodiode electrode and an opposing electrode in Patent Document 1, it is reported that a solid material (fiber-type substance) is arranged to contain the electrolyte solution in the electrolyte layer between the dye-sensitization photodiode electrode and the opposing electrode.

A photoelectric conversion device is reported in Patent Document 2 comprising an active electrode having a semiconductor film coated with dye, an opposing electrode arranged opposite the active electrode and a solid layer formed by a polymer porous film sandwiched between the active electrode and the opposing electrode such that the electrolyte solution is contained in an air gap of the solid layer.

A photoelectric conversion device having a conducting supporting member, a semiconductor fine-particle layer with dye adsorption that is coated on the conducting supporting member, a charge-transfer layer and an opposing electrode is reported in Patent Document 3, and the reported photoelectric conversion device provides a spacer layer containing essentially insulating particles between the semiconductor fine-particle layer and the opposing electrode.

Furthermore, for example, previous methods such as the following are disclosed in Patent Document 4 for methods of manufacturing such dye-sensitized solar cells. In other words, the periphery of the inside air space formed by a conducting glass substrate comprising a porous titanium oxide layer and another conducting glass substrate comprising an opposing electrode layer in mutual opposition is subsequently completely sealed and hardened by heat treatment of a glass frit seal member at 450° C. Then, after injecting a dye solution in the air space between the conducting glass substrate and the other conducting glass substrate and adsorbing dye into the titanium oxide layer, an electrolyte solution is filled into the air space, and finally injection holes that were formed in the conducting glass substrate or the other conducting glass substrate are sealed.

By this method, during the first seal in which heat treatment is performed at high temperature, the dye is not yet adsorbed on the titanium oxide layer, and the electrolyte solution is not yet filled in the air space. Therefore deterioration of the dye and the electrolyte solution by heat treatment during sealing is prevented and a reliable seal is possible, thus ensuring high photoelectric conversion efficiency and reliability.

### Patent Document 1: Japanese Unexamined Patent Publication No. 2000-357544

### Patent Document 2: Japanese Unexamined Patent Publication No. 11-339866

### Patent Document 3: Japanese Unexamined Patent Publication No. 2000-294306

### Patent Document 4: Japanese Unexamined Patent Publication No. 2000-348783

Non-Patent Document 1: Johokiko Co., Ltd. publication “Leading Edge Technologies and Future Trends in Dye-sensitized and other Solar Cells” P26-P27 (published Apr. 25, 2003)

### DISCLOSURE OF THE INVENTION

### Problems to be Solved by the Invention

However, as in the constitutions of Patent Documents 1, 2 and 3, in the case of a cell structure wherein two substrates of a photosensitive electrode substrate and an opposing electrode substrate are attached together, it is difficult to manufacture the device, where a gap with which electrolyte is filled between the surface of the porous titanium oxide layer supporting dye and the opposing electrode surface is kept narrowly and constant, and therefore, it is difficult to manufacture the device ensuring high photoelectric conversion efficiency, stability and reliability.

Regarding the constitutions in Patent Document 3, a spacer layer formed by insulating-type fine particles on an oxide-semiconductor fine-particle layer is simultaneously formed and sintered simultaneously. However, whereas the mean particle size of the oxide-semiconductor fine particles is small at 10 nm, the mean particle size of alumina powder which is an insulating fine particle is large at 0.8 μm, and the mean particle size of low-melting glass powder is also large at 0.5 μm. A problem arises in the case of alumina powder because a mean particle size of 0.8 μm cannot be achieved by sintering at the sintering temperature of semiconductor fine particles (about 500° C.), and if the sintering temperature is raised any higher, the crystalline structure of the oxide semiconductor changes, which impairs the high conversion efficiency.

Other problems exist such as the following.

According to constitutions such as that of Non-Patent Document 1, the photosensitive electrode substrate is normally formed by a glass substrate (also referred to hereafter as “FTO glass substrate”) coated with a conductive film such as SnO₂:F (F doped SnO₂).

By forming a porous titanium oxide layer with a thickness of 10 μm or more on this FTO glass substrate by high-temperature sintering after applying the paste, internal stress occurs in the porous titanium oxide layer that is formed.

The FTO film of this FTO glass substrate is heat-resistant, and although the sheet resistance and the light-transmitting property do not change even at the sintering temperature of titanium oxide, the sheet resistance is high as compared to that of light-transmitting conductive films made of indium-type oxides (such as ITO and In₂O₃). Therefore, glass substrates having ITO films with low sheet resistances are preferable, but ITO films encounter the problem of deterioration of sheet resistance and light-transmitting property at the sintering temperature of titanium oxide, and therefore indium-type oxides (such as ITO and In₂O₃) could not be used.

Also, regarding FTO glass substrates, the sheet resistance is about 10 Ω/□ (square), so when the photoelectric conversion device size becomes 1 cm or more, the resistance loss becomes high and the FF (fill factor) becomes low, and thus high conversion efficiency cannot be obtained.

Furthermore, in the methods of manufacturing dye-sensitized solar cells as conventional photoelectric conversion devices as disclosed in Patent Document 4, increasing the number and size of the injection holes makes it difficult to reliably seal the injection holes, and it is therefore difficult to maintain sufficient conversion efficiency and reliability.

Therefore, the present invention was completed in view of the problems of the prior art recited above, and therefore the objects of the present invention are as follows.

In other words, instead of attaching two substrates together, an object is to reduce the number of substrates by laminating layers on one substrate forming a single body.

Previously, the thickness of the electrolyte layer was determined by a gap between two substrates, and another object of the present invention is to allow determination according to the thickness of a spacer layer containing an electrolyte that does not depend on the gap, such that the electrolyte layer can be made both thin and uniform, and the conversion efficiency and reliability can be improved.

Furthermore, an object of this invention is to reduce the negative effects on conducting substrates due to internal stress occurring in a porous semiconductor layer even when high-temperature sintering method is used to form the porous semiconductor layer; increase the degrees of freedom of material selection of the light-transmitting conductive layer for the subsequent step or steps of formation of the porous semiconductor layer; and improve conversion efficiency to thus allow the easy formation of a collecting electrode.

In addition, an object of the present invention is to make possible the use of low-temperature sintering paste when forming the collecting electrode such that the degrees of freedom of the material selection of the same is improved, low temperature are possible, and production costs are reduced.

Yet another object of the present invention is to allow the formation of porous titanium oxide layers of large surface areas that are both level and uniform such that reliability is improved.

A further object of the present invention is to easily form a plurality of photoelectric conversion devices on one conducting substrate such that integration is excellent, and to make a photoelectric conversion device from multiple laminations thereby providing a photoelectric conversion device with excellent lamination properties.

A still further object of the present invention is to allow the reliable sintering of a porous spacer layer comprising fine particles.

Yet a still further object of the present invention is to provide a photoelectric conversion device and a method of manufacturing the same to achieve high conversion efficiency, excellent reliability as well as greatly improved suitability for mass production.

Finally, an object of the present invention is to provide a laminated body comprising a singular laminated structure formed by laminating layers on one conducting substrate, after which a dye is adsorbed (supported) through a permeation layer and the entirety is immersed in an electrolyte solution, such that the deterioration of prior art of the dye and the electrolyte that occurs due to steps such as heat treatment during lamination of the light-transmitting conductive layer after adsorbing (supporting) the dye and injecting the electrolyte is prevented, and as a result the conversion efficiency is improved.

### Means for Solving the Problems

The photoelectric conversion device of the present invention includes a conducting substrate; an opposing electrode layer formed on the conducting substrate; a porous spacer layer containing an electrolyte and formed on the opposing electrode layer; a porous semiconductor layer that adsorbs a dye and contains the electrolyte, and that is formed on the porous spacer layer; and a light-transmitting conductive layer formed on the semiconductor layer.

In the photoelectric conversion device of the present invention, a light-transmitting sealing layer is preferably formed such that an upper surface and a side surface of a laminated body are covered and the electrolyte is sealed therein, wherein the laminated body comprises the opposing electrode layer, the porous spacer layer, the semiconductor layer and the light-transmitting conductive layer respectively laminated in this order on the conducting substrate.

In the photoelectric conversion device of the present invention, the semiconductor layer preferably comprises a sintered body of oxide-semiconductor fine particles and the mean particle size of the oxide-semiconductor fine particles preferably becomes progressively smaller in the thickness direction progressing away from a side of the conducting substrate.

In the photoelectric conversion device of the present invention, the porous spacer layer is preferably a porous body comprising fine particles of an insulator or a p-type semiconductor.

In the photoelectric conversion device of the present invention, an interface between the porous spacer layer and the semiconductor layer preferably comprises an uneven face.

In the photoelectric conversion device of the present invention, the opposing electrode layer preferably comprises a porous body containing the electrolyte.

The method of manufacturing a photoelectric conversion device of the present invention includes the steps of: laminating an opposing electrode layer, a porous spacer layer, a porous semiconductor layer and a light-transmitting conductive layer in this order on a conducting substrate to form a laminated body; opening a plurality of through holes that pass completely through the conducting substrate and the opposing electrode layer; injecting a dye through the through holes such that the dye is adsorbed into the semiconductor layer; injecting an electrolyte into the interior of the laminated body; and capping the through holes.

The method of manufacturing a photoelectric conversion device of the present invention includes the steps of: laminating an opposing electrode layer, a porous spacer layer and a porous semiconductor layer in this order on a conducting substrate to form a laminated body; immersing the laminated body in a dye solution such that the dye is adsorbed into the semiconductor layer; forming a light-transmitting conductive layer laminated on the semiconductor layer; and finally permeating an electrolyte into the porous spacer layer and the semiconductor layer from at least a side surface of the laminated body.

The method of manufacturing a photoelectric conversion device of the present invention includes the steps of: laminating an opposing electrode layer, a porous spacer layer, a porous semiconductor layer and a light-transmitting conductive layer in this order on a conducting substrate to form a laminated body; immersing the laminated body in a dye solution such that the dye is adsorbed into the semiconductor layer from a side surface of the laminated body; and finally permeating an electrolyte into the porous spacer layer and the semiconductor layer from at least a side surface of the laminated body.

The photoelectric conversion device of the present invention includes a laminated body including an opposing electrode layer, a porous spacer layer, a porous semiconductor layer that contains an electrolyte, adsorbs a dye and a light-transmitting conducting layer, which are laminated in this order on a conducting substrate, a porous light-transmitting coating layer into which the dye is transmitting and that covers a side surface and an upper surface of the laminated body, and a light-transmitting sealing layer that covers and seals the surface of the light-transmitting coating layer.

In the photoelectric conversion device of the present invention, the light-transmitting coating layer preferably may have vacancies of a size that can prevent leakage of an electrolytic solution from its surface to an exterior due to surface tension.

In the photoelectric conversion device of the present invention, the thickness of the light-transmitting coating layer may be more than that of the light-transmitting sealing layer.

The method of manufacturing a photoelectric conversion device of the present invention, that is the method of manufacturing any one of the photoelectric conversion devices having the above-mentioned constitutions of the present invention, includes the steps of: laminating an opposing electrode layer, a porous spacer layer, a porous semiconductor layer and a light-transmitting conductive layer in this order on a conducting substrate to form a laminated body; and forming a porous light-transmitting coating layer that covers a side surface and an upper surface of the laminated body. Next, a dye is adsorbed through the light-transmitting coating layer from an exterior into the semiconductor layer, and then an electrolyte solution is injected through the light-transmitting coating layer from an exterior into an interior of the light-transmitting coating layer. Finally, the surface of the light-transmitting coating layer is covered with a light-transmitting sealing layer.

In the method of manufacturing a photoelectric conversion device of the present invention, it is preferable that when adsorbing the dye from the exterior through the light-transmitting coating layer into the semiconductor layer, the conducting substrate where the laminated body and the light-transmitting coating are formed is immersed in a solution containing a dye.

In the method of manufacturing a photoelectric conversion device of the present invention, it is preferable that a solution containing the dye is stirred.

The photoelectric conversion device of the present invention includes a laminated body comprising an opposing electrode layer, a permeation layer into which an electrolyte solution permeates and inside which the permeated solution is contained, a porous semiconductor layer that adsorbs a dye and a light-transmitting conductive layer, which are laminated in this order on a conducting substrate, the laminated body having the electrolyte contained in the semiconductor layer and the permeation layer.

In the photoelectric conversion device of the present invention, it is preferable that the arithmetic mean roughness of the surface or a fractured surface of the permeation layer is larger than the arithmetic mean roughness of the surface or a fractured surface of the semiconductor layer.

In the photoelectric conversion device of the present invention, it is preferable that the arithmetic mean roughness of the surface or a fractured surface of the permeation layer is in the range from 0.1 to 0.5 μm.

In the photoelectric conversion device of the present invention, the permeation layer may comprise a sintered body formed by sintering at least one selected from insulator particles and oxide semiconductor particles.

In the photoelectric conversion device of the present invention, the permeation layer may comprise a sintered body formed by sintering at least one of aluminum oxide particles and titanium oxide particles.

The photoelectric conversion device of the present invention may include a light-transmitting sealing layer that seals the electrolyte by covering an upper surface and a side surface of the laminated body.

The method of manufacturing a photoelectric conversion device of the present invention includes the step of laminating an opposing electrode layer, a permeation layer into which an electrolyte solution permeates and inside which the solution is contained, a porous semiconductor layer and a light-transmitting conductive layer in this order on a conducting substrate to form a laminated body. Next, the laminated body is immersed in a dye solution, wherein the dye is adsorbed into the semiconductor layer through the permeation layer, and finally the electrolyte solution is permeated through the permeation layer into the semiconductor layer.

The photoelectric power generation device of the present invention is provided such that the photoelectric conversion device of the present invention is utilized as means of electrical power generation, and the electrical power generated by the means of electrical power generation is supplied to a load.

### EFFECTS OF THE INVENTION

The photoelectric conversion device of the present invention includes a conducting substrate; an opposing electrode layer formed on the conducting substrate; a porous spacer layer containing an electrolyte formed on the opposing electrode layer; a porous semiconductor layer that adsorbs a dye and contains the electrolyte, and that is formed on the porous spacer layer; and a light-transmitting conductive layer formed on the semiconductor layer. Therefore, the porous spacer layer is formed on a substrate at the opposing electrode side (a conducting substrate and an opposing electrode layer) and a laminated body (a porous semiconductor layer and a light-transmitting conductive layer) at the photosensitive electrode side is laminated thereon using the porous spacer layer as a supporting layer, and thus the substrate at the photosensitive electrode can be omitted, and also low cost and simplification of the structure can be achieved.

Since two electrodes are not interposed between two substrates, unlike prior art, it is easy to remove the electrodes.

Even if the porous semiconductor layer is not formed on the substrate at a photosensitive electrode side but formed on a substrate at the opposing electrode side, the porous semiconductor layer can be formed at a light-incident side, and thus high conversion efficiency is obtained.

The thickness of the electrolyte layer determined previously by a gap between two substrates is allowed to be determined according to the thickness of a porous spacer layer, and thus the electrolyte layer can be made both thin and uniform, and the conversion efficiency and reliability can be improved.

The porous semiconductor layer formed by applying a paste comprising oxide-semiconductor fine particles such as titanium oxide particles, water and a surfactant, and sintering the paste at high temperature shows good conversion efficiency. In the present invention, since a light-transmitting conductive layer can be formed after forming the porous semiconductor layer, adhesion between the porous semiconductor layer and the light-transmitting conductive layer can be improved, and the conversion efficiency and reliability are improved. Moreover, since a light-transmitting conductive layer is formed after forming the porous semiconductor layer, the degree of freedom of selection of the material of the light-transmitting conductive layer increases and, for example, an indium-based (ITO, In₂O₃, etc.) light-transmitting conductive layer with low heat resistance and low sheet resistance can be used, and as a result the conversion efficiency can be further improved.

Even if a high-temperature sintering method is employed in the formation of the porous semiconductor layer, an adverse influence of internal stress on a conducting substrate can be decreased because the porous spacer layer as an undercoat layer is formed.

Even if a high-temperature treatment is employed in the sintering of fine particles for formation of the porous semiconductor layer, the light-transmitting conductive layer may be formed at low temperature because the light-transmitting conductive layer is formed in the subsequent step. As a result, the degree of freedom of selection of the material of the light-transmitting conductive layer increases and manufacturing cost can be decreased.

Also, since a collecting electrode can be formed on the light-transmitting conductive layer of the laminated body comprising the opposing electrode layer, the porous spacer layer, the semiconductor layer and the light-transmitting conductive layer laminated in this order on the conducting substrate, resistance decreases and the conversion efficiency increases, and thus the size of the photoelectric conversion device can be increased.

Also, a conductive paste for formation at low temperature, that enables low cost and simple process, can be used, thus making it possible to decrease manufacturing cost.

Furthermore, since only one substrate may be used, it is easy to achieve integration and lamination of a photoelectric conversion device. Namely, a plurality of photoelectric conversion devices are arranged on one substrate and series connection and parallel connection can be freely selected and also desired voltage and current can be output. Also, it is easy to laminate the photoelectric conversion device. Namely, a laminated photoelectric conversion device comprising a plurality of photoelectric conversion devices laminated on one substrate causes small loss even when the voltage increases.

In the photoelectric conversion device of the present invention, a light-transmitting sealing layer is preferably formed such that an upper surface and a side surface of a laminated body are covered and the electrolyte is sealed therein, wherein the laminated body comprises the opposing electrode layer, the porous spacer layer, the semiconductor layer and the light-transmitting conductive layer respectively laminated in this order on the conducting substrate. Therefore, it is possible to ensure reliability by suppressing deterioration due to contamination of the dye and the electrolyte with air.

In the photoelectric conversion device of the present invention, the porous semiconductor layer preferably comprises a sintered body of oxide-semiconductor fine particles and the mean particle size of the oxide-semiconductor fine particles becomes progressively smaller in the thickness direction progressing away from a side of the conducting substrate. Therefore, it is possible to reflect and scatter easily transmitting long wavelength light on oxide-semiconductor fine particles with a larger particle size according to a site of the porous semiconductor layer near to the conducting substrate side, thus making it possible to improve a light confinement effect and to improve the conversion efficiency.

In the photoelectric conversion device of the present invention, the porous spacer layer is preferably a porous body comprising fine particles of an insulator or a p-type semiconductor. Therefore, the porous spacer layer plays a role of a supporting layer capable of supporting the upper layer such as a porous semiconductor layer and also has an electric insulating action (prevention of short circuiting), and thus the photoelectric conversion device can be formed of one substrate without laminating two substrates.

Also, since a conventional porous oxide-semiconductor is an n-type semiconductor, a porous spacer layer is used as a p-type semiconductor, and therefore, reverse electron transfer is suppressed by blocking (insulting) transportation of electrons from a porous oxide-semiconductor to a porous spacer layer, and the porous spacer layer can help a photoelectric converting action because holes have transportability. In a reverse relation, when the porous oxide-semiconductor is a p-type semiconductor, the porous spacer layer preferably comprises an n-type semiconductor.

The porous spacer layer is capable of filling the pore section of the porous body with an electrolyte and therefore can efficiently perform an oxidation-reduction reaction. Since the thickness of the porous spacer layer containing the electrolyte can be controlled both thin and uniform with good reproducibility, the width (thickness) of the electrolyte layer can be controlled both thin and uniform, and as a result electric resistance decreases and also the conversion efficiency and reliability are improved. The width of the electrolyte layer does not depend on the flatness of the conducting substrate, but depends on the thickness of the porous spacer layer, and thus the electrolyte layer can be formed by a uniform coating technique of the prior art. Even if large area size, integration and lamination of the photoelectric conversion device are realized, current loss and voltage loss due to thickness unevenness of the electrolyte layer are not so large and thus a photoelectric conversion device with excellent characteristics can be manufactured even if large area size is realized.

Since the porous spacer layer exists between the conducting substrate and the opposing electrode layer, and the porous semiconductor layer, the porous spacer layer can absorb internal stress of the porous semiconductor layer produced during high-temperature sintering, thus making it possible to prevent cracking of the conducting substrate and peeling of the porous semiconductor layer as a result of direct application of internal stress to the conducting substrate.

The porous spacer layer comprising fine particles of an inorganic insulator or a p-type semiconductor can be sintered before sintering the porous semiconductor layer. Therefore, the mean particle size of fine particles of the porous spacer layer can be made larger than that of fine particles of the porous semiconductor layer. Consequently, the volume of the electrolyte increases, thus exerting the effect of decreasing electric resistance of the electrolyte and improving the conversion efficiency.

In the photoelectric conversion device of the present invention, an interface between the porous spacer layer and the porous semiconductor layer preferably comprises an uneven face. Therefore, light passed through the porous semiconductor layer is scattered, bringing about a light confinement effect, thus making possible further improvement of the conversion efficiency.

In the photoelectric conversion device of the present invention, the opposing electrode layer preferably comprises a porous body containing the electrolyte. Therefore, the surface area of the opposing electrode layer can be increased and the conversion efficiency can be improved by improving the oxidation-reduction reaction and hole transporting properties.

According to the method of manufacturing a photoelectric conversion device of the present invention, an opposing electrode layer, a porous spacer layer, a porous semiconductor layer and a light-transmitting conductive layer are laminated in this order on a conducting substrate to form a laminated body, and then a plurality of through holes that pass completely through the conducting substrate and the opposing electrode layer are opened. After injecting a dye through the through holes such that the dye is adsorbed into the semiconductor layer, and injecting an electrolyte into the interior of the laminated body, the through holes are capped. Consequently, a photoelectric conversion device with various operations and effects described above can be manufactured.

Since the light-transmitting conductive layer can be formed before dye adsorption, a high-temperature treatment can be used in the formation of the light-transmitting conductive layer, thus exerting the effects of allowing wider selection in the material of the light-transmitting conductive layer and the formation method, and improving conductivity of the light-transmitting conductive layer.

According to the method of manufacturing a photoelectric conversion device of the present invention, a laminated body comprising an opposing electrode layer, a porous spacer layer and a porous semiconductor layer is formed in this order on a conducting substrate, and then the laminated body is immersed in a dye solution such that the dye is adsorbed into the porous semiconductor layer. A light-transmitting conductive layer is laminated on the porous semiconductor layer, and then an electrolyte is permeated into the porous spacer layer and the porous semiconductor layer from at least a side surface of the laminated body. Consequently, a photoelectric conversion device with various operations and effects described above can be manufactured.

Also, since dye adsorption can be performed before forming the light-transmitting conductive layer, dye adsorption can be performed more securely, and thus the conversion efficiency is improved.

According to the method of manufacturing a photoelectric conversion device of the present invention, an opposing electrode layer, a porous spacer layer, a porous semiconductor layer and a light-transmitting conductive layer are laminated in this order on a conducting substrate to form a laminated body, and the laminated body is immersed in a dye solution such that the dye is adsorbed into the porous semiconductor layer from a side surface of the laminated body, and then an electrolyte is permeated into the porous spacer layer and the porous semiconductor layer from at least a side surface of the laminated body. Consequently, a photoelectric conversion device with various operations and effects described above can be manufactured.

Since the light-transmitting conductive layer can be formed before dye adsorption, a high-temperature treatment can be used in the formation of the light-transmitting conductive layer, thus exerting the effects of allowing wider selection in the material of the light-transmitting conductive layer and the formation method, and improving conductivity of the light-transmitting conductive layer.

The photoelectric conversion device of the present invention includes a laminated body including an opposing electrode layer, a porous spacer layer, a porous semiconductor layer that contains an electrolyte, adsorbs a dye and a light-transmitting conducting layer, which are laminated in this order on a conducting substrate, a porous light-transmitting coating layer into which the dye is transmitting and that covers a side surface and an upper surface of the laminated body, and a light-transmitting sealing layer that covers and seals the surface of the light-transmitting coating layer. Consequently, the porous light-transmitting coating layer is formed with a large number of fine pores with a size enough to adsorb the dye, and thus the fine pores are uniformly distributed on the entire surface of the light-transmitting sealing layer when the light-transmitting sealing layer is laminated thereon thinly and smoothly. Therefore, even if stress produced by heat is applied to an interface between the light-transmitting coating layer and the light-transmitting sealing layer, the stress is uniformly applied to the interface, and thus the sealed state can be stably maintained and a photoelectric conversion device having excellent reliability can be obtained.

When the electrolyte is a solid electrolyte, since the electric resistance is larger than a liquid electrolyte of the prior art, the conversion efficiency decreases by about 30%. When the above laminated body is formed, like the present invention, the thickness of the electrolyte layer can be remarkably decreased, thus exerting the effect of obtaining high conversion efficiency even if the electrolyte is a solid electrolyte.

According to the photoelectric conversion device of the present invention, when the light-transmitting coating layer comprises vacancies of a size that prevents leakage due to surface tension of an electrolyte solution from the surface to the exterior, the inside of the laminated body is filled with an electrolytic solution and the light-transmitting coating layer is sealed with the light-transmitting sealing body while maintaining a state where it is hard to incorporate outside air, and thus it becomes difficult to incorporate outside air into the laminated body and deterioration of the laminated body and the electrolytic solution due to outside air can be prevented.

According to the photoelectric conversion device of the present invention, when the thickness of the light-transmitting coating layer is more than that of the light-transmitting sealing layer, even if the thickness of the light-transmitting sealing layer is less than that of the light-transmitting coating layer, a porous light-transmitting coating layer is securely sealed, and thus the resulting photoelectric conversion device has a merit that it is thin and lightweight, and also it has a smooth surface, and therefore dust scarcely adheres thereto and it is easy to remove stains.

According to the method of manufacturing a photoelectric conversion device of the present invention, that is any one of the methods of manufacturing a photoelectric conversion device with the above constitutions of the present invention, an opposing electrode layer, a porous spacer layer, a porous semiconductor layer and a light-transmitting conductive layer are laminated in this order on a conducting substrate to form a laminated body, and then a porous light-transmitting coating that covers a side surface and an upper surface of the laminated body is formed. A dye is adsorbed through the light-transmitting coating layer from the exterior into the porous semiconductor layer and an electrolyte solution is injected through the light-transmitting coating layer from an exterior into an interior of the light-transmitting coating, and then the surface of the light-transmitting coating layer is covered with a light-transmitting sealing layer. As described above, after forming the porous light-transmitting coating layer, the dye is adsorbed or the electrolytic solution is injected, and therefore the dye and the electrolytic solution do not deteriorate due to a heat treatment until a light-transmitting coating layer as primary sealing, and deterioration of the dye and the electrolytic solution due to a treatment upon manufacturing can be suppressed as possible, and thus good conversion efficiency can be obtained. Regarding the porous light-transmitting coating layer, since a large number of fine pores with a size enough to adsorb the dye are uniformly opened, the solution containing the dye and the electrolytic solution can be quickly immersed and injected through the porous light-transmitting coating layer, thus making it possible to remarkably improve the productivity.

According to the method of manufacturing a photoelectric conversion device of the present invention, when the laminated body and the conducting substrate comprising the light-transmitting coating layer are immersed in a solution containing a dye when adsorbing the dye from an exterior through the light-transmitting coating layer into the porous semiconductor layer, a photoelectric conversion device can be manufactured by a simple process of immersing in a solution containing a dye as compared with the process of injecting a solution containing a dye into the laminated body, or discharging the solution.

According to the method of manufacturing a photoelectric conversion device of the present invention, when a solution containing the dye is stirred, the rate of adsorbing the dye can be increased, thus making it possible to further improve the productivity.

According to the photoelectric conversion device of the present invention, an opposing electrode layer, a permeation layer into which an electrolyte solution permeates and inside which the permeated solution is contained, a porous semiconductor layer containing a dye adsorbed therein, and a light-transmitting conductive layer are laminated in this order on a conducting substrate to form a laminated body containing an electrolyte contained in the porous semiconductor layer and the permeation layer. Consequently, since a permeation layer is formed on a substrate at the opposing electrode side (a conducting substrate and an opposing electrode layer) and a laminated portion (a porous semiconductor layer and a light-transmitting conductive layer) at the photosensitive electrode side is laminated thereon using the permeation layer as a supporting layer, the substrate at the photosensitive electrode (light-transmitting substrate, etc.) used in prior art can be omitted, and also low cost and simplification of the structure can be achieved.

After forming the laminated body, by adsorbing a dye through a permeation layer and immersing an electrolyte solution into the laminated body through the permeation layer, it is possible to prevent prior art deterioration of the dye and the electrolyte that occurs due to steps such as heat treatment during lamination of the light-transmitting conductive layer after adsorbing the dye and injecting the electrolyte, and as a result conversion efficiency is improved.

When the electrolyte is a permeable solid electrolyte such as a gel electrolyte, the conversion efficiency decreases by about 30%, because the electric resistance is larger than the conventional liquid electrolyte. When the above laminated body is formed like the present invention, the thickness of the electrolyte layer can be remarkably decreased, thus exerting the effect of obtaining high conversion efficiency even if the electrolyte is a solid electrolyte.

In the light-transmitting conductive layer to be laminated on the porous semiconductor layer, the light-transmitting conductive layer, which is formed at high temperature, exhibits good adhesion with the porous semiconductor layer, high light-transmitting property and high conductivity. In the present invention, however, since the dye is adsorbed through the permeation layer after forming the laminated body, and also an electrolyte solution is permeated into the laminated body through the permeation layer, a light-transmitting conductive layer can be formed without causing deterioration of the dye and the electrolyte, and thus the conversion efficiency and reliability are improved.

According to the photoelectric conversion device of the present invention, the arithmetic mean roughness of the surface or a fractured surface of the permeation layer is preferably larger than the arithmetic mean roughness of the surface or a fractured surface of the semiconductor layer. Therefore, the mean particle size of fine particles constituting the permeation layer is larger than that of the porous semiconductor layer. In this case, since the size of vacancies in the permeation layer increases, a large amount of the electrolyte can exist in the permeation layer adjacent to the opposing electrode layer, and thus electric resistance of the electrolyte contained in the permeation layer decreases and the conversion efficiency can be improved.

Since the arithmetic mean roughness of the surface or a fractured surface of the permeation layer is preferably in the range from 0.1 to 0.5 μm, it is easy to permeate an electrolytic solution through the permeation layer and also the dye can be sufficiently adsorbed into the porous semiconductor layer.

According to the photoelectric conversion device of the present invention, the permeation layer preferably comprises a sintered body in which at least one of insulator particles and oxide-semiconductor particles are sintered, and the permeation layer also plays a role of a supporting layer capable of supporting the porous semiconductor layer, and thus a photoelectric conversion device can be formed of one substrate without laminating two substrates.

The permeation layer itself is a porous body and the pore section of the porous body can be filled with the electrolyte, and thus an oxidation-reduction reaction can be efficiently performed. Since the thickness of the permeation layer supporting the electrolyte can be controlled both thin and uniform with good reproducibility, the width (thickness) of the permeation layer as the electrolyte layer supporting the electrolyte can be controlled both thin and uniform, and as a result electric resistance decreases and also the conversion efficiency and reliability are improved. The width of the electrolyte layer does not depend on the flatness of the substrate, but depends on the thickness of the permeation layer, and thus the electrolyte layer can be formed by using a uniform coating technique conventionally employed. Even if large area size, integration and lamination of the photoelectric conversion device are realized, current loss and voltage loss due to thickness unevenness of the electrolyte layer are not so large, and thus a photoelectric conversion device with excellent characteristics can be manufactured even if large area size is realized.

When the permeation layer comprises insulator particles, the permeation layer plays a role of a supporting layer capable of supporting a porous semiconductor layer and also has an electric insulating action (prevention of short circuiting), and thus short circuiting between the porous semiconductor layer and the opposing electrode layer can be prevented and also the conversion efficiency can be improved.

According to the photoelectric conversion device of the present invention, the permeation layer preferably comprises a sintered body formed by sintering at least one type of particles selected from an aluminum oxide and a titanium oxide. Therefore, adhesion between the permeation layer and the porous semiconductor layer can be improved, and also the conversion efficiency and reliability can be improved.

When the permeation layer comprises aluminum oxide particles as insulator particles, short circuiting between the porous semiconductor layer and the opposing electrode layer can be prevented, and also the conversion efficiency can be improved.

It is preferable that the permeation layer comprises titanium oxide particles which are oxide-semiconductor particles, because an electronic energy band gap is in the range from 2 to 5 eV that is larger than that in the case of visible light, thus exerting the effect that it does not absorb light in a wavelength range where the dye absorbs.

According to the method of manufacturing a photoelectric conversion device of the present invention, an opposing electrode layer, a permeation layer into which an electrolyte solution permeates and inside which the solution is contained, a porous semiconductor layer and a light-transmitting conductive layer are laminated in this order on a conducting substrate to form a laminated body. The laminated body is immersed in a dye solution, wherein the dye is adsorbed into the porous semiconductor layer through the permeation layer, and then the electrolyte solution is permeated through the permeation layer into the porous semiconductor layer. Consequently, a photoelectric conversion device with various operations and effects described above can be manufactured.

Since the light-transmitting conductive layer can be formed before dye adsorption, a high-temperature treatment can be used in the formation of the light-transmitting conductive layer, thus exerting the effects of allowing wider selection in the material of the light-transmitting conductive layer and the formation method, and improving light-transmitting ability and electric conductivity for the light-transmitting conductive layer.

According to the photoelectric power generation device of the present invention, the photoelectric conversion device of the present invention is utilized as means of electrical power generation, and the electrical power generated by the means of electrical power generation is supplied to a load. Therefore, a highly reliable photoelectric power generation device having high conversion efficiency can be obtainable by utilizing the effect capable of stably obtaining excellent photoelectric conversion characteristics in which the width of the electrolyte is thin and uniform, which is the effect of the photoelectric conversion device of the present invention.

### BRIEF DESCRIPTION OF THE DRAWINGS

FIG. 1 is a schematic sectional view showing an example of the first embodiment of a photoelectric conversion device of the present invention.

FIG. 2 is a schematic sectional view showing a manufacturing method of FIG. 1.

FIG. 3 is a schematic sectional view showing another example of a manufacturing method of FIG. 1.

FIG. 4 is a schematic sectional view showing an example of the second embodiment according to a photoelectric conversion device of the present invention.

FIG. 5 is a schematic sectional view showing an example of the third embodiment according to a photoelectric conversion device of the present invention.

FIG. 6 is a schematic sectional view showing a manufacturing method of FIG. 5.

FIG. 7 is a schematic sectional view showing another example of a manufacturing method of FIG. 5.

### PREFERRED EMBODIMENTS FOR CARRYING OUT THE INVENTION

### First Embodiment

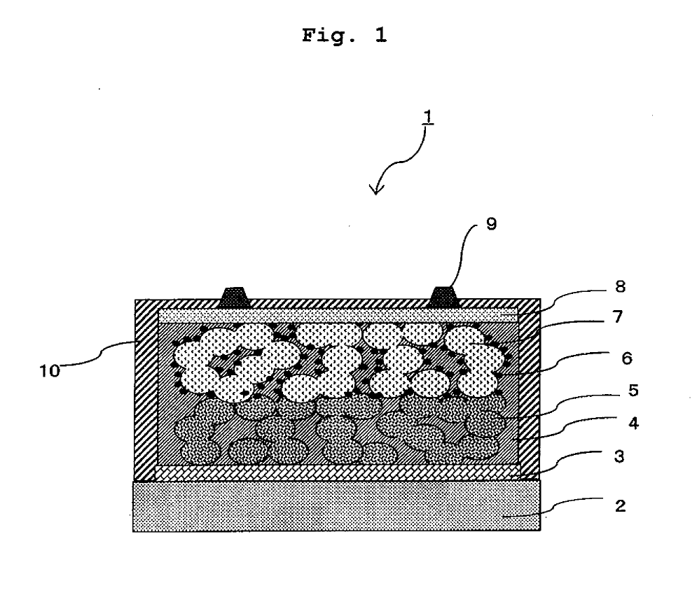

Herewith, the first embodiment of the present invention relating to a photoelectric conversion device, a method of manufacturing the same and an photoelectric power generation device is described in detail below with reference to FIG. 1 through FIG. 3. The same reference numerals are used for the same members in the drawings.

FIG. 1 is a cross-sectional view of a photoelectric conversion device of the present invention. The photoelectric conversion device 1 of FIG. 1 comprises a singular laminated body formed by an opposing electrode layer 3, a porous spacer layer 5 containing an electrolyte 4, a porous semiconductor layer 7 that adsorbs (loads) a dye 6 as well as contains the electrolyte 4 and a light-transmitting conductive layer 8 that are laminated in this order on a conducting substrate 2.

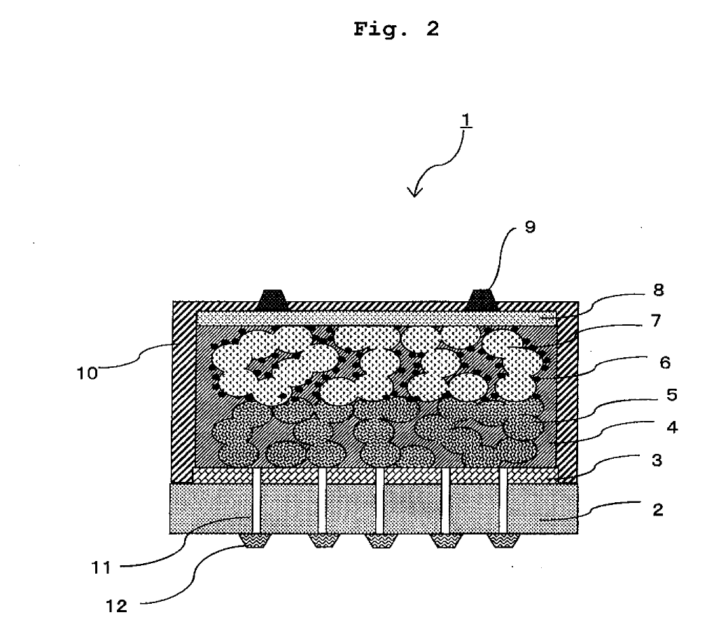

The method of manufacturing the photoelectric conversion device 1 of FIG. 1 (herein referred to as “manufacturing method A”) comprises the following steps: an opposing electrode layer 3, a porous spacer layer 5, a porous semiconductor layer 7 and a light-transmitting conductive layer 8 are laminated in this order on a conducting substrate 2 to form a laminated body; then a plurality of through holes (reference numeral 11 of FIG. 2) that passes completely through both the conducting substrate 2 and the opposing electrode layer 3 is opened; a dye 6 is injected through the through holes 11 and the dye 6 is adsorbed into the porous semiconductor layer 7; an electrolyte 4 is injected into the inside of the laminated body; and finally the through holes 11 are capped by a sealing member 12.

In other words, according to the manufacturing method A recited above, there is provided a photoelectric conversion device 1 comprising an opposing electrode layer 3, a porous spacer layer 5 containing an electrolyte 4, a porous semiconductor layer 7 that adsorbs a dye 6 and contains an electrolyte 4 and a light-transmitting conductive layer 8 that are laminated in this order on a conducting substrate 2 to form a laminated body wherein a plurality of through holes 11 is opened in the conducting substrate 2 as shown in FIG. 2.

Another method of manufacturing the photoelectric conversion device 1 of FIG. 1 (herein referred to as “manufacturing method B”) comprises the following steps: an opposing electrode layer 3, a porous spacer layer 5 and a porous semiconductor layer 7 are laminated in this order on a conducting substrate 2 to form a laminated body; the laminated body is subsequently immersed in a solution of dye 6 such that the dye 6 is adsorbed into the porous semiconductor layer 7 of the laminated body; a light-transmitting conductive layer 8 is then laminated on the porous semiconductor layer 7; and finally an electrolyte 4 permeates into the porous spacer layer 5 and the porous semiconductor layer 7 from at least a side surface of the laminated body.

Another method of manufacturing the photoelectric conversion device 1 of FIG. 1 (herein referred to as “manufacturing method C”) comprises the following steps: an opposing electrode layer 3, a porous spacer layer 5, a porous semiconductor layer 7 and a light-transmitting conductive layer 8 are laminated in this order on a conducting substrate 2 to form a laminated body; the laminated body is immersed in a solution of dye 6 such that the dye 6 is adsorbed into the porous semiconductor layer 7 from a side surface of the laminated body; and finally an electrolyte 4 permeates into the porous spacer layer 5 and the porous semiconductor layer 7 from at least a side surface of the laminated body.

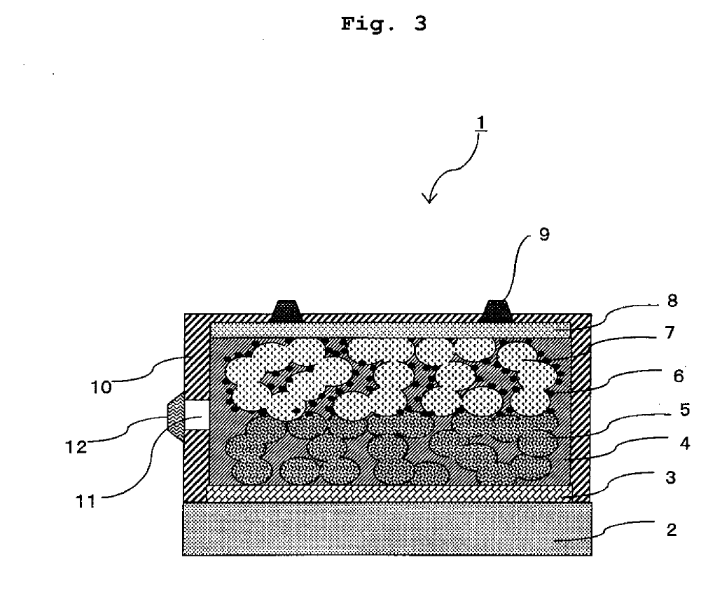

In other words, according to the manufacturing method B and C recited above, as shown in FIG. 3, a photoelectric conversion device 1 comprises the following: a laminated body formed by an opposing electrode layer 3, a porous spacer layer 5 containing an electrolyte 4, a porous semiconductor layer 7 that adsorbs a dye 6 as well as contains an electrolyte 4 and a light-transmitting conductive layer 8 laminated in this order on a conducting substrate 2; a light-transmitting sealing layer 10 that seals the electrolyte 4 and covers an upper surface and a side surface of the laminated body; and a through hole 11 opened to allow permeation of the dye 6 and the electrolyte 4 into a side of the light-transmitting sealing layer 10.

Herewith, the elements comprised in the photoelectric conversion device 1 recited above will be described in detail below.

### <Conducting Substrate>

The conducting substrate 2 may have non-light-transmitting property and includes, for example, a thin sheet comprising titanium, stainless steel, aluminum, silver, copper, nickel, or carbon; a substrate in which a resin layer or conductive resin layer containing a metal fine particles or a metal microfine fiber therein is formed on the surface of an insulating substrate; or a substrate in which the surface of an insulating substrate is coated with a titanium layer, a stainless steel layer or a conductive metal oxide layer so as to prevent corrosion with the electrolyte 4.

When the conducting substrate 2 has light reflectivity, a glossy thin metal substrate made of aluminum, silver, copper, nickel, titanium or stainless steel may be used alone, or a light-transmitting conductive layer (impurity-doped metal oxide layer) such as a SnO₂:F layer may be formed on a metal substrate so as to prevent corrosion due to the electrolyte 4.

Also, the conducting substrate 2 may be a substrate in which a metal layer or a light-transmitting conductive layer is formed on an insulating substrate. The insulating substrate may be either non-light-transmitting or light-transmitting. When these conducting substrates 2 are light-transmitting, light can be made incident from either of both faces of a principal surface of the photoelectric conversion device 1, and thus the conversion efficiency can be improved by making light to be incident from both faces of the principal surface.

The material of the insulating substrate may be an inorganic material, for example, glass such as white plate glass, soda glass or borosilicate glass, ceramics; a resin material such as polyethylene terephthalate (PET), polycarbonate (PC), acryl, polyethylene naphthalate (PEN) or polyimide; or an organic inorganic hybrid material. The metal layer may be formed of a thin film comprising titanium, aluminum, stainless steel, silver, copper or nickel using a vacuum deposition method or a sputtering method.

When the conducting substrate 2 is obtained by forming a light-transmitting conductive layer on an insulating substrate, the light-transmitting conductive layer is particularly preferably an impurity-(F, Sb, etc.) doped tin oxide film (SnO₂ film) or an impurity-(Ga, Al, etc.) doped zinc oxide film (ZnO film) because it has heat resistance. The light-transmitting conductive layer may be obtained by laminating a Ti layer, an ITO layer and a Ti layer in this order, and is a laminated film having improved adhesion and corrosion resistance.

The thickness of the conducting substrate 2 may be in the range from 0.005 to 5 mm, and preferably from 0.01 to 2 mm, in view of the mechanical strength. When the conducting substrate 2 is obtained by forming a conductive layer on an insulating substrate, the thickness of the conductive layer is in the range from 0.001 to 10 μm, and preferably from 0.05 to 2.0 μm.

### <Opposing Electrode Layer>

The opposing electrode layer 3 is preferably an ultrathin film having a catalyst function made of platinum or carbon. In addition, a film obtained by electrodeposition of an ultrathin film of gold (Au), palladium (Pd) or aluminum (Al) is exemplified. When a porous film is comprised of fine particles of these materials, for example, a porous film of carbon fine particles is used, the surface area of the opposing electrode layer 3 increases, thus making it possible to contain the electrolyte 4 in the pore section and to improve the conversion efficiency.

### <Porous Spacer Layer>

The porous spacer layer (porous insulating layer) 5 may be a thin film comprising a porous body obtained by sintering alumina fine particles. As shown in FIG. 1, the porous spacer layer 5 is formed on the opposing electrode layer 3.

An aluminum oxide (Al₂O₃) may be most suited for use as the material or composition of the porous spacer layer 5, and other material may be an insulating (electronic energy band gap is 3.5 eV or more) metal oxide such as silicon oxide (SiO₂).

When the porous spacer layer is a porous body comprising a collection of these granular bodies, acicular bodies, columnar bodies and/or the like, the porous spacer layer can contain the electrolyte 4 thus allowing improved conversion efficiency.

The porous spacer layer 5 may be a porous body having porosity in the range from 20 to 80%, and more preferably from 40 to 60%. The mean particle size or the mean fiber diameter of the granular body, the acicular body and the columnar body, each constituting the porous spacer layer 5, may be in the range from 5 to 800 nm, and more preferably from 10 to 400 nm. This is because miniaturization of the mean particle size or the mean fiber diameter of the material is not possible for the lower limit of 5 nm or less, and the sintering temperature increases when the upper limit of 800 nm is exceeded.

When the porous spacer layer 5 is a porous body, the surface of the porous spacer layer 5 or the porous semiconductor layer 7 and the interface comprise an uneven face, bringing about a light confinement effect, thus making possible further improvement of the conversion efficiency.

The porous spacer layer 5 made of alumina is manufactured by the following procedure. First, acetylacetone is added to an Al₂O₃ fine powder and the mixture is kneaded with deionized water to prepare a paste of aluminum oxide stabilized with a surfactant. The paste thus prepared is applied on an opposing electrode layer 3 at a given rate using a doctor blade method or a bar coating method, and then subjected to a heat treatment in atmospheric air at 300 to 600° C., preferably at 400 to 500° C., for 10 to 60 minutes, preferably for 20 to 40 minutes, to form the porous spacer layer 5.

When the porous spacer layer 5 comprises an inorganic p-type metal oxide-semiconductor, the material is preferably CoO, NiO, FeO, Bi₂O₃, MoO₂, Cr₂O₃, SrCu₂O₂ or CaO—Al₂O₃, and MOS₂ may be used.

When the porous spacer layer 5 comprises an inorganic p-type compound semiconductor, the material may be CuI, CuInSe₂, Cu₂O, CuSCN, Cu₂S, CuInS₂, CuAlO, CuAlO₂, CuAlSe₂, CuGaO₂, CuGaS₂ or CuGaSe₂, each containing a monovalent copper, and may also be GaP, GaAs, Si, Ge, or SiC.

The low-temperature growth method of the porous spacer layer 5 may be an electrodeposition method, a cataphoretic electrodeposition method or a hydrothermal synthesis method.

The thickness of the porous spacer layer 5 may be in the range from 0.01 to 300 μm, and preferably from 0.05 to 50 μm.

When the porous spacer layer 5 is a charge transporting layer made of a p-type semiconductor such as nickel oxide, the formation method is as follows. First, ethyl alcohol is added to a powder of a p-type semiconductor and the mixture is kneaded with deionized water to prepare a paste of a p-type semiconductor stabilized with a surfactant. The paste thus prepared is applied on an opposing electrode layer 3 at a given rate using a doctor blade method or a bar coating method and then subjected to a heat treatment in atmospheric air at 300 to 600° C., preferably at 400 to 500° C., for 10 to 6.0 minutes, preferably for 20 to 40 minutes, to form a charge transporting layer of a p-type semiconductor of a porous body. This technique is simple and is effective when the porous spacer layer can be preliminarily formed on a heat-resistant substrate. In order to form a charge transporting layer made of a p-type semiconductor by forming a pattern in plan view, it is preferred to use a screen printing method as compared with a doctor blade method and a bar coating method.

The low-temperature growth method of the charge transporting layer made of a porous p-type semiconductor is preferably an electrodeposition method, a cataphoretic electrodeposition method or a hydrothermal synthesis method. The charge transporting layer is preferably subjected to a microwave treatment, a plasma treatment or a UV irradiation treatment as a post-treatment for improving hole transportation characteristics. When the p-type semiconductor comprises nickel oxide, it is preferably made of nickel oxide having a molecular structure in which nanoparticles are arranged in the form of a fiber by adjusting the kind and the amount of additives to be added to the material solution and devising sintering conditions.

The sintering temperature of fine particles constituting the porous spacer layer 5 is preferably higher than the sintering temperature of the porous semiconductor layer 7 and also the mean particle size of fine particles is preferably larger than the mean particle size of the porous semiconductor layer 7. In this case, electric resistance of the electrolyte 4 decreases, thus making it possible to improve the conversion efficiency.

The porous spacer layer 5 is formed for electric insulation between the semiconductor layer 7 and the opposing electrode layer 3, and also functions as a spacer between the semiconductor layer 7 and the opposing electrode layer 3. It is preferred that the porous spacer layer 5 has a thickness that is uniform and is as small as possible, and is porous so as to contain the electrolyte 4. As the thickness of the porous spacer layer 5 decreases, namely, the oxidation-reduction reaction distance or the hole transportation distance decreases, the conversion efficiency improves. Also, when the thickness of the porous spacer layer 5 becomes more uniform, a large-area photoelectric conversion device with high reliability can be realized.

### <Porous Semiconductor Layer>

The porous semiconductor layer 7 is preferably a porous n-type oxide-semiconductor layer made of titanium dioxide. As shown in FIG. 1, the porous semiconductor layer 7 is formed on the porous spacer layer 5.

Titanium oxide (TiO₂) is most suited for use as the material or composition of the porous semiconductor layer 7 and the other material may be a metal oxide-semiconductor made of at least one kind of metal element such as titanium (Ti), zinc (Zn), tin (Sn), niobium (Nb), indium (In), yttrium (Y), lanthanum (La), zirconium (Zr), tantalum (Ta), hafnium (Hf), strontium (Sr), barium (Ba), calcium (Ca), vanadium (V) and tungsten (W). Also, the material may contain one or more kinds of non-metal elements such as nitrogen (N), carbon (C), fluorine (F), sulfur (S), chlorine (Cl) and phosphorus (P). It is preferable that titanium oxide has an electronic energy band gap in the range from 2 to 5 eV that is larger than the energy of visible light. The porous semiconductor layer 7 may be an n-type semiconductor in which the conduction band is lower than that of the dye 6 in an electronic energy level.

Because the porous semiconductor layer 7 is a porous body comprising a granular body, a fibrous body such as an acicular body, tubular body or columnar body, or a collection of these various fibrous bodies, such that the surface area that adsorbs the dye 6 increases thus allowing improved conversion efficiency. It is preferable for the porous semiconductor layer 7 to be a porous body having a void fraction of 20% to 80%, and more preferably 40% to 60%. Porosity allows the surface area of the photosensitive electrode layer to be improved by a factor of 1,000 or more as compared to that of a non-porous body, and thus good efficiency of optical sorption, photoelectric conversion and electronic conduction can be obtained. It is preferable that the shape of the porous semiconductor layer 7 is such that the surface area of the same is large and the electrical resistance is low, for example that obtained by a composition of fine particles or a fine fibrous body. The mean particle size or the mean fiber diameter of the same is in the range from 5 to 500 nm, and more preferably from 10 to 200 nm. This is because miniaturization of the mean particle size or the mean fiber diameter of material is not possible for the lower limit of 5 nm or less, and the contacting surface area becomes small and thus photocurrent becomes markedly low when the upper limit of 500 nm is exceeded.

Furthermore, by using a porous body as the porous semiconductor layer 7, the surface of the dye-sensitized photoelectric converting body formed by adsorbing the dye 6 into the same becomes the surface of depressions and protrusions, bringing about a light confinement effect, thus making possible further improvement of the conversion efficiency.

The thickness of the porous semiconductor layer 7 is in the range from 0.1 to 50 μm, and more preferably from 1 to 20 μm. This is because the photoelectric converting action markedly decreases and practical use is not possible for the lower limit of 0.1 μm or less, and light does not permeate and light is not made incident when the upper limit of 50 μm is exceeded.

When the porous semiconductor layer 7 comprises titanium oxide, it is formed by the following procedure. First, acetylacetone is added to a TiO₂ anatase powder and the mixture is kneaded with deionized water to prepare a paste of titanium oxide stabilized with a surfactant. The paste thus prepared is applied on a porous spacer layer 5 at a given rate using a doctor blade method or a bar coating method and then subjected to a heat treatment in atmospheric air at 300 to 600° C., preferably at 400 to 500° C., for 10 to 60 minutes, preferably for 20 to 40 minutes to form a porous semiconductor layer 7. This technique is simple and is preferable.

The low-temperature growth method of the porous semiconductor layer 7 is preferably an electrodeposition method, a cataphoretic electrodeposition method or a hydrothermal synthesis method. The porous semiconductor layer is preferably subjected to a microwave treatment, a plasma treatment using a CVD method, a thermal catalyst treatment or a UV irradiation treatment as a post-treatment for improving electron transportation characteristics. The porous semiconductor layer 7 formed by the low-temperature growth method is preferably porous ZnO formed by the electrodeposition method or porous TiO₂ formed by the cataphoretic electrodeposition method.

The porous surface of the porous semiconductor layer 7 is preferably subjected to a TiCl₄ treatment, namely, a treatment of immersing in a TiCl₄ solution for 10 hours, washing with water and sintering at 450° C. for 30 minutes, because electron conductivity is improved, thus improving the conversion efficiency.

Also, an ultrathin dense layer of an n-type oxide-semiconductor may be inserted between the porous semiconductor layer 7 and the light-transmitting conductive layer 8, because reverse current can be suppressed, thus improving the conversion efficiency.

It is preferable that the porous semiconductor layer 7 comprises a sintered body of oxide-semiconductor fine particles and the mean particle size of oxide-semiconductor fine particles becomes progressively smaller progressing away from a side of the conducting substrate 2. For example, the porous semiconductor layer 7 preferably comprises a laminated body of two layers each having a different mean particle size of oxide-semiconductor fine particles. Specifically, oxide-semiconductor fine particles having a small mean particle size are used at a side of the light-transmitting conductive layer 8 and oxide-semiconductor fine particles having a large mean particle size are used at a side of the porous spacer layer 5, bringing about a light confinement effect of light scattering and light reflection in the porous semiconductor layer 7 at a side of the porous spacer layer 5 having a large mean particle size, thus making possible improvement of the conversion efficiency.

More specifically, it is preferable that 100% (% by weight) of oxide-semiconductor fine particles having a mean particle size of about 20 nm are used as those having a small mean particle size and 50% by weight of oxide-semiconductor fine particles having a mean particle size of about 20 nm and 50% by weight of oxide-semiconductor fine particles having a mean particle size of about 180 nm are used in combination as those having a large mean particle size. An optimum light confinement effect is obtained by varying the weight ratio, the mean particle size and the film thickness. By increasing the number of layers from 2 to 3 or forming these layers so as not to produce a boundary between them, the mean particle size can become progressively smaller progressing away from a side of the conducting substrate 2 (a side of the porous spacer layer 5).

### <Light-Transmitting Conductive Layer>

The light-transmitting conductive layer 8 may be a tin-doped indium oxide film (ITO film) or an impurity-doped indium oxide film (In₂O₃ film) formed by a low-temperature growth sputtering method or a low-temperature spray pyrolysis method. An impurity-doped zinc oxide film (ZnO film) formed by a solution growth method is also preferable and these films may be laminated before use. Also, a fluorine-doped tin dioxide film (SnO₂:F film) formed by a thermal CVD method may be used.

Examples of other film formation method of the light-transmitting conductive layer 8 include a vacuum deposition method, an ion plating method, a dip coating method and a sol-gel method. By the growth of these films, the surface of the light-transmitting conductive layer 8 preferably comprises an uneven face in a wavelength order of incident light and more preferably brings about a light confinement effect.

The light-transmitting conductive layer 8 may be a thin metal film made of Au, Pd or Al formed by a vacuum deposition method or a sputtering method.

### <Collecting Electrode>

The collecting electrode 9 is obtained by applying a conductive paste comprising conductive particles made of silver, aluminum, nickel, copper, tin and carbon, an epoxy resin as an organic matrix, and a curing agent and firing the conductive paste. The conductive paste is particularly preferably an Ag paste or an Al paste, and both a low-temperature paste and a high-temperature paste can be used.

### <Light-Transmitting Sealing Layer>

In FIG. 1, a light-transmitting sealing layer 10 is provided so as to prevent leakage of an electrolyte 4 to the exterior, increase mechanical strength, protect a laminated body and prevent deterioration of a photoelectric conversion function as a result of direct contact with the external environment.

The material of the light-transmitting sealing layer 10 is particularly preferably a fluororesin, a silicone polyester resin, a high-weatherability polyester resin, a polycarbonate resin, an acrylic resin, a PET (polyethylene terephthalate) resin, a polyvinyl chloride resin, an ethylene-vinyl acetate (EVA) copolymer resin, polyvinyl butyral (PVB), an ethylene-ethyl acrylate (EEA) copolymer, an epoxy resin, a saturated polyester resin, an amino resin, a phenol resin, a polyamideimide resin, a UV curing resin, a silicone resin, an urethane resin or a coating resin used for a metal roof because it is excellent in weatherability.

The thickness of the light-transmitting sealing layer 10 may be in the range from 0.1 μm to 6 mm, and preferably from 1 μm to 4 mm. Sealing performances deteriorate when the thickness is less than 0.1 μm, while light transmittance of the light-transmitting sealing layer 10 deteriorates when the thickness exceeds 6 mm. Also, by imparting antidazzle properties, heat shielding properties, heat resistance, low staining properties, antimicrobial, mildew resistance, design properties, high workability, scratching/abrasion resistance, snow slipperiness, antistatic properties, far-infrared radiation properties, acid resistance, corrosion resistance and environment adaptability to the light-transmitting sealing layer 10, reliability and merchantability can be improved more.

### <Dye>

The dye 6 as a sensitizing dye is preferably a ruthenium-tris, ruthenium-bis, osmium-tris or osmium-bis type transition metal complex, a multinuclear complex, a ruthenium-cis-diaqua-bipyridyl complex, phthalocyanine, porphyrin, a polycyclic aromatic compound, or a xanthene-based dye such as rhodamine B.

In order to adsorb the dye 6 into the porous semiconductor layer 7, it is effective that the dye 6 has at least one carboxyl group, sulfonyl group, hydroxamic acid group, alkoxy group, aryl group and phosphoryl group as a substituent. Herein, the substituent preferably enables strong chemical adsorption of the dye 6 itself into the porous semiconductor layer 7 and easy transfer of charges from the dye 6 in an excitation state to the porous semiconductor layer 7.

The method of adsorbing the dye 6 into the porous semiconductor layer 7 includes, for example, a method of immersing the porous semiconductor layer 7 formed on the conducting substrate in a solution containing the dye 6 dissolved therein.

In the present invention, a dye 6 is adsorbed to a porous semiconductor layer 7 during the process of the manufacturing method. Namely, in the manufacturing method in which a laminated body comprising an opposing electrode layer 3, a porous spacer layer 5, a porous semiconductor layer 7 and a light-transmitting conductive layer 8 laminated in this order on a conducting substrate 2 is formed; a plurality of through holes 11 that pass completely through both the conducting substrate 2 and the opposing electrode layer 3 are formed; a dye 6 is injected through the through holes 11 and the dye 6 is adsorbed into the porous semiconductor layer 7; an electrolyte 4 is injected into the inside of the laminated body; and finally the through holes 11 are capped by a sealing member 12, the dye 6 is adsorbed into the porous semiconductor layer 7.

Alternatively, in the manufacturing method in which a laminated body comprising an opposing electrode layer 3, a porous spacer layer 5 and a porous semiconductor layer 7 laminated in this order on a conducting substrate 2 is formed; the laminated body is immersed in a dye 6 solution such that the dye 6 is adsorbed into the porous semiconductor layer 7; a light-transmitting conductive layer 8 is laminated on the porous semiconductor layer 7; an electrolyte 4 is permeated into the porous spacer layer 5 and the porous semiconductor layer 7 from at least a side surface of the laminated body, the dye 6 is adsorbed into the porous semiconductor layer 7.

Alternatively, in the manufacturing method in which a laminated body comprising an opposing electrode layer 3, a porous spacer layer 5, a porous semiconductor layer 7 and a light-transmitting conductive layer 8 laminated in this order on a conducting substrate 2 is formed; the laminated body is immersed in a dye 6 solution such that the dye 6 is adsorbed into the porous semiconductor layer 7 from at least a side surface of the laminated body; an electrolyte 4 is permeated into the porous spacer layer 5 and the porous semiconductor layer 7 from at least a side surface of the laminated body; and the dye 6 is adsorbed into the porous semiconductor layer 7.

As the solvent of the solution into which the dye 6 is dissolved, for example, alcohols such as ethanol; ketones such as acetone; ethers such as diethylether; and nitrogen compounds such as acetonitrile are used alone or a mixture of two or more kinds of them. The concentration of the dye in the solution is preferably in the range from about 5×10⁻⁵ to 2×10⁻³ mol/l (liter: 1,000 cm³).

There are no restrictions on the solution and temperature conditions of the atmosphere in the case of immersing the conducting substrate 2 with the porous semiconductor layer 7 formed thereon in the solution containing the dye 6 dissolved therein. For example, the conducting substrate 2 is immersed in the solution under atmospheric pressure or a vacuum at room temperature or while heating. The immersion time can be appropriately controlled according to the kind of dye 6 and solution, and the concentration of the solution. Consequently, the dye 6 can be adsorbed into the porous semiconductor layer 7.

### <Electrolyte>

Examples of the electrolyte 4 include an electrolyte solution, an ion-conductive electrolyte such as a gel electrolyte or a solid electrolyte, and an organic hole-transporting material.

As the electrolyte solution, a solution of a quaternary ammonium salt or a Li salt is used. The electrolyte solution to be used can be prepared by mixing ethylene carbonate, acetonitrile or methoxypropionitrile with tetrapropylammonium iodide, lithium iodide or iodine.

The gel electrolyte is roughly classified into a chemical gel and a physical gel. Regarding the chemical gel, a gel is formed by a chemical bond through a crosslinking reaction or the like, while a gel is formed at approximately room temperature through a physical interaction regarding the physical gel. The gel electrolyte is preferably a gel electrolyte obtained by mixing acetonitrile, ethylene carbonate, propylene carbonate or a mixture thereof with a host polymer such as polyethylene oxide, polyacrylonitrile, polyvinylidene fluoride, polyvinyl alcohol, polyacrylic acid or polyacrylamide and polymerizing the mixture. When the gel electrolyte or the solid electrolyte is used, it is possible to gelatinize or solidify by mixing a precursor with low viscosity and a porous semiconductor layer 7 and causing a two-dimensional or three-dimensional crosslinking reaction through means such as heating, ultraviolet irradiation or electron beam irradiation.

The ion-conductive solid electrolyte is preferably a solid electrolyte including a salt such as a sulfone imidazolium salt, a tetracyanoquinodimethane salt or a dicyanoquinodiimine salt in polyethylene oxide or a polymer chain of polyethylene oxide or polyethylene. As the molten salt of iodide, for example, an iodide such as an imidazolium salt, a quaternary ammonium salt, an isooxazolidinium salt, an isothiazolidinum salt, a pyrazolidium salt, a pyrrolidinium salt or a pyridinium salt can be used.

Examples of the molten salt of the iodide may include 1,1-dimethylimidazolium iodide, 1-methyl-3-ethylimidazolium iodide, 1-methyl-3-pentylimidazolium iodide, 1-methyl-3-isopentylimidazolium iodide, 1-methyl-3-hexylimidazolium iodide, 1-methyl-3-ethylimidazolium iodide, 1,2-dimethyl-3-propylimidazole iodide, 1-ethyl-3-isopropylimidazolium iodide and pyrrolidinium iodide.

Applications of the photoelectric conversion device 1 of the present invention are not limited to solar batteries. The photoelectric conversion device having a photoelectric conversion function can be utilized and can be applied to various photodetectors and optical sensors.

A photoelectric power generation device can be provided such that the above photoelectric conversion device 1 is utilized as means of electrical power generation, and the electrical power generated by the means of electrical power generation is supplied to a load. Namely, one photoelectric conversion device 1 described above is used. Alternatively, when using a plurality of photoelectric conversion devices, those connected in series, in parallel or in serial-parallel are used as means of electrical power generation and electrical power may be directly supplied to a DC load from the means of electrical power generation. Also, there can be used an electrical power generation device capable of supplying the electrical power to a commercial power supply system or an AC load of various electrical equipment after converting the means of photoelectrical power generation into a suitable AC electric power through electrical power conversion means such as an inverter. Furthermore, such an electrical power generation device can be utilized as a photoelectric power generation device of solar power generating systems of various aspects by building with a sunny aspect. Consequently, a photoelectric power generation device with high efficiency and durability can be provided.

### Second Embodiment

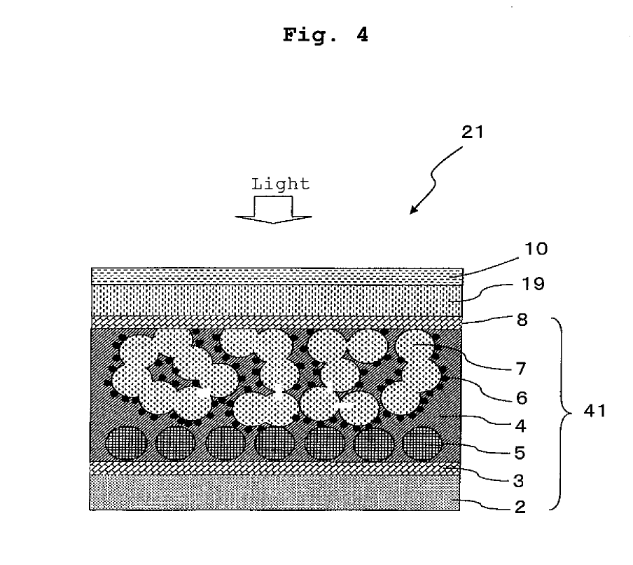

A schematic sectional view showing an example of a second embodiment according to a photoelectric conversion device of the present invention is shown in FIG. 4. The photoelectric conversion device 21 shown in FIG. 4 includes a laminated body 41 including an opposing electrode layer 3, a porous spacer layer 5, a porous semiconductor layer 7 that contains an electrolyte 4 and adsorbs a dye 6 and a light-transmitting conducting layer 8 laminated in this order on a conducting substrate 2, a porous light-transmitting coating 19 into which the dye 6 is transmitting and that covers a side surface and an upper surface of the laminated body 41, and a light-transmitting sealing layer 10 that covers and seals the surface of the light-transmitting coating layer 19. The arrow in the drawing indicates the incident direction of light.

With the above constitution, the porous light-transmitting coating layer 19 is formed with a large number of fine pores with a size enough to adsorb the dye 6, and thus the fine pores are uniformly distributed on the entire surface of the light-transmitting sealing layer 10 when the light-transmitting sealing layer 10 is laminated thereon thinly and smoothly. Therefore, even if stress produced by heat is applied to an interface between the light-transmitting coating layer 19 and the light-transmitting sealing layer 10, the stress is uniformly applied to the interface, and thus the sealed state can be stably maintained and a photoelectric conversion device having excellent reliability can be obtained.

According to the manufacturing method of the photoelectric conversion device 21 shown in FIG. 4, an opposing electrode layer 3, a porous spacer layer 5, a porous semiconductor layer 7 and a light-transmitting conducting layer 8 are laminated in this order on a conducting substrate 2 to form a laminated body 41; and then a porous light-transmitting coating layer 19 that covers a side surface and an upper surface of the laminated body 41 is formed. A dye 6 is adsorbed through the light-transmitting coating layer 19 from the exterior into the porous semiconductor layer 7; and an electrolyte solution (a liquid electrolyte 4) is injected through the light-transmitting coating layer 19 from the exterior into the interior of the light-transmitting coating 19; and then the surface of the light-transmitting coating layer 19 is covered with a light-transmitting sealing layer 10.

With the above constitution, after forming the porous light-transmitting coating layer 19, the dye 6 is immersed or the electrolytic solution is injected. Therefore, the dye 6 or the electrolytic solution are not deteriorated by a heat treatment until the light-transmitting coating layer 19 as primary sealing is formed and deterioration of the dye 6 or the electrolytic solution due to the treatment upon manufacturing can be suppressed as much as possible, and thus good conversion efficiency can be obtained. Also, since the porous light-transmitting coating layer 19 is formed with a large number of fine pores with a size enough to adsorb the dye 6, a solution containing the dye 6 or an electrolytic solution can be quickly immersed or injected through the porous light-transmitting coating layer 19, thus making it possible to markedly improve the productivity.

### <Light-transmitting Coating Layer>

With the above constitution, it is possible to suitably use, as the light-transmitting coating layer 19, a porous SOG (Spin On Grass) film containing silicon dioxide (SiO₂) as a main component. The porous SOG film is obtained by using an organic silane solution containing an organic silane, water, an alcohol, an acid or an alkali, and a surfactant, forming the organic silane solution into a film, and subjecting the film to a heat treatment.

The organic silane is, for example, a hydrolyzable organic oxysilane such as TEOS (tetraethoxysilane) or TMOS (tetramethoxysilane), and the surfactant is preferably a halogenated alkyltrimethylammonium-based cationic surfactant selected from cationic surfactants such as lauryltrimethylammonium chloride, n-hexadecyltrimethylammonium chloride, alkyltrimethylammonium bromide, cetyltrimethylammonium chloride, cetyltrimethylammonium bromide, stearyltrimethylammonium chloride, alkyldimethylethylammonium chloride, alkyldimethylethylammonium bromide, cetyldimethylethylammonium bromide, octadecyldimethylethylammonium bromide and methyldodecylbenzyltrimethylammonium chloride.

As the acid or alkali for hydrolysis, an inorganic acid such as nitric acid or hydrochloric acid, an organic acid such as formic acid, and an alkali such as ammonia can be used.

The porous SOG film using an organic silane may be formed with the thickness of about 0.5 μm by applying using a spin coating method or a dip coating method and subjecting to a heat treatment using a known electric furnace. By repeating such a treatment multiple times, a SOG film having a thickness of about 1 to several μm is formed as the light-transmitting coating layer 19. The size of vacancies formed in the SOG film can be controlled by the amount of a surfactant added and the temperature of the heat treatment. For example, vacancies can be formed by vaporization of the surfactant when the solvent such as water or alcohol is vaporized in air at a temperature in the range from about 150 to 350° C. and then the surfactant is vaporized at a temperature in the range from about 200 to 500° C. under reduced pressure of less than 100 Pa, and thus vacancies having a size in the range from 1 nm to several tens of nanometers can be formed in the SOG film.

Regarding the vacancies to be formed in the SOG film, a silanol group (Si—OH) usually exists on the surface and an electrostatic interaction is exerted between the silanol group, and the dye 6 solution and the electrolytic solution that are passed through the light-transmitting coating layer 19 via the vacancies, and it becomes difficult to pass the dye 6 solution or the electrolytic solution containing the organic solvent even if the size of vacancies is large to some extent. Therefore, the porous SOG film is hydrophobized by treating with a silylation agent.

In this case, the silylation agent includes an organic silicon compound that is capable of introducing an organic group having a silicon atom (hereinafter also referred to as a silyl group) through a reaction with a compound having an active hydrogen such as a silanol group, and is represented by the following general formula:

RₙSiX_{(4-n).} (1)

wherein n is an integer of 1 to 3, R is a non-hydrolyzable organic group, and X is a hydrolyzable group, a hydrogen atom or a halogen atom, or

R₃SiYSiR₃ (2)

wherein R is a non-hydrolyzable organic group, and Y is a hydrolyzable group.

In the above formulas (1) and (2), examples of the non-hydrolyzable organic group represented by R include an alkyl group such as a methyl group, an ethyl group, or a propyl group; an alkenyl group such as a vinyl group; an aryl group such as a phenyl group; an aralkyl group such as a benzyl group; and a substituted alkyl group such as a fluoroalkyl group, a glycidyloxyalkyl group, an acryloyloxyalkyl group, a methacryloyloxyalkyl group, an aminoalkyl group or a mercaptoalkyl group.

Examples of the monovalent hydrolyzable group represented by X include an alkoxy group such as a methoxy group, an ethoxy group, or a propoxy group; a methylcarbonyloxy group; an acyloxy group such as an ethylcarbonyloxy group; and an amino group, an alkylamino group, a dialkylamino group, an imidazolyl group and an alkyl sulfonate group.

In the above formula (2), examples of the divalent hydrolyzable group represented by Y include an imino group, an ureylene group, a sulfonyl dioxy group, an oxycarbonylamino group, and an oxyalkylimino group.

In the above formulas (1) and (2), a plurality of Rs are included in a molecule and each R may be the same or different.

Specific examples of the silylation agent represented by the formula (1) include trimethylsilanes such as trimethylchlorosilane, trimethylbromosilane, trimethylsilylmethane sulfonate, trimethylsilyltrifluoromethane sulfonate, N,N-diethylaminotrimethylsilane, N,N-dimethylaminotrimethylsilane, and N-trimethylsilylimidazole; long chain alkylsilanes such as ethyldimethylchlorosilane, isopropyldimethylchlorosilane, triethylchlorosilane, triisopropylchlorosilane, t-butyldimethylchlorosilane, t-butyldimethylsilylimidazole, amyldimethylchlorosilane, and octadecyldimethylchlorosilane; aromatic group-containing silanes such as phenyldimethylchlorosilane, benzyldimethylchlorosilane, and diphenylmethylchlorosilane; fluorine-containing silanes such as (trifluoromethyl)dimethylchlorosilane, (pentafluoroethyl)dimethylchlorosilane, and (pentafluoroethyl)di(trifluoromethyl)chlorosilane; hydrosilanes such as trimethylsilane; difunctional silanes such as dimethyldiethoxysilane and di-t-butyldichlorosilane; trifunctional silanes such as methyltrichlorosilane and ethyltrichlorosilane; and silane coupling agents such as vinyltrichlorosilane, γ-glycidoxypropyltrimethoxysilane, γ-methacryloxypropyltrimethoxysilane, γ-aminopropyltriethoxysilane, and γ-mercaptopropyltrimethoxysilane.

Specific examples of the silylation agent represented by the above formula (2) include polyhydric silicon silanes having two or more silicon atoms in the molecule, such as hexamethyldisilazane, bis(trimethylsilyl)sulfate, N,O-bis(trimethylsilyl)carbamate, bis(trimethylsilyl)acetoamide, bis(trimethylsilyl)urea, and hexamethylcyclotrisilazane. On these silylation agents, fluorine-containing silanes are preferred in view of the fact that hydrophobicity of a SOG film is markedly improved. Specifically, trimethylchlorosilane, hexamethyldisilazane and (trifluoromethyl)dimethylchlorosilane are particularly preferred.

In order to treat the porous SOG film using such a silylation agent, the SOG film is exposed to steam of the silylation agent, or the SOG film is immersed in a solution of the silylation agent and the solution is heated.

The light-transmitting coating layer 19 preferably comprises vacancies of a size that prevents leakage due to surface tension of an electrolyte solution from the surface to the exterior. In order to prevent leakage, the size of the vacancies is preferably adjusted to a small size at 40 nm. In this case, the laminated body 41 is filled with the electrolytic solution and the light-transmitting coating layer 19 is sealed by the light-transmitting sealing layer 10 while maintaining a state where outside air such as air is hardly incorporated. Therefore, outside air is less likely to be incorporated into the laminated body 41 and deterioration of the laminated body 41 and the electrolytic solution due to outside air can be prevented. In this case, it is possible to quickly permeate the electrolytic solution into the laminated body 41 from the exterior through the light-transmitting coating layer 19 without causing deterioration and to prevent leakage of the electrolytic solution permeated into the laminated body 41. Here, the electrolytic solution can be permeated more satisfactorily by means of applying an external pressure in which the conducting substrate 2 formed on the laminated body 41 is immersed in the electrolytic solution and the pressure is returned to normal pressure after entirely evacuating.

The light-transmitting coating layer 19 is preferred because it is a porous SOG film subjected to a silylation treatment and therefore a solution of dye 6 and an electrolytic solution can be quickly permeated into the laminated body 41 through interior holes from the exterior in the state of coating the laminated body 41 without causing deterioration in a dye-sensitized solar battery. The porous SOG film subjected to a silylation treatment is also preferred because it exhibits high light transmittance to sunlight.

The light-transmitting coating layer 19 is not limited only to such a constitution and, for example, a light-transmitting inorganic material such as titanium oxide (TiO₂) or zinc oxide (ZnO) may be used in addition to silicon dioxide (SiO₂). It is also possible to use, in addition to the SOG film, nanowhiskers made of known porous glass or columnar deposits.

### <Light-Transmitting Sealing Layer>

The light-transmitting sealing layer 10 may be made of an organic silicon compound. Specifically, using any of trimethylsilyl isocyanate, dimethylsilyl diisocyanate, methylsilyl triisocyanate, vinylsilyl triisocyanate and phenyl triisocyanate, a solution prepared by diluting with a proper solvent is applied on a light-transmitting coating layer 19 and unnecessary moisture is vaporized by heating at a low temperature of about 300° C. or lower under reduced pressure. Thus, vacancies on the surface of the light-transmitting coating layer 19 can be securely capped with an organic compound in the form of a thin film. In this case, since the treatment temperature is a low temperature, deterioration of the dye 6 and the electrolytic solution can be suppressed.

The thickness of the light-transmitting coating layer 19 is preferably larger than that of the light-transmitting sealing layer 10. The thickness of the light-transmitting coating layer 19 is preferably in the range from about 1 to 50 μm. When the thickness is less than 1 μm, an uneven face at a side of a lower layer cannot be securely coated. In contrast, when the thickness is more than 50 μm, stress applied to the side of the lower layer increases, and thus peeling of the lower layer is likely to occur.

The thickness of the light-transmitting sealing layer 10 is preferably in the range from about 0.2 to 20 μm. When the thickness is less than 0.2 μm, a sealing function becomes insufficient. In contrast, when the thickness exceeds 20 μm, stress applied to a side of the lower layer increases, and thus peeling of the lower layer is likely to occur.

When such a light-transmitting coating layer 19 and a light-transmitting sealing layer 10 are used, by laminating the light-transmitting coating layer 19 and the light-transmitting sealing layer 10 on the laminated body 41, a dye-sensitized solar battery as a cell can be formed, and thus it is advantageous in view of thinning and weight reduction of the cell.

Other constituent elements are described below.

### <Conducting Substrate>

The conducting substrate 2 may be a thin metal sheet alone, and is made of titanium, stainless steel, aluminum, silver or copper. Also, a resin sheet obtained by permeating fine particles of carbon or metal, and microfine fibers is preferred. Also, it is preferred to use an insulating sheet formed with a metal thin film made of titanium, stainless steel, aluminum, silver or copper, a transparent conductive film made of ITO, a SnO₂: F (F-doped SnO₂) layer, a ZnO:Al (Al-doped ZnO) layer, or a multi-layered structure conductive film such as a Ti layer/ITO layer/Ti layer. The insulating sheet is preferably a resin sheet made of PET (polyethylene terephthalate), PEN (polyethylene naphthalate), polyimide or polycarbonate, an inorganic sheet made of soda glass, borosilicate glass or ceramic, or an organic inorganic hybrid sheet.

When the conducting substrate 2 is provided with light reflectivity, it is possible to reuse by reflecting transmitted light. In the case of a metal sheet, a reflective layer is preferably made of silver or aluminum. When the reflective layer is a conductive film, a multi-layered laminated film such as a Ti layer/Ag layer/Ti layer with silver (Ag) or an adhesion layer (Ti layer) is preferred, and is preferably formed by a vacuum deposition method, an ion plating method, a sputtering method or an electrolytic deposition method.

The thickness of the conducting substrate 2 is in the range from 0.01 to 5 mm, and preferably from 0.01 to 0.5 mm.

### <Opposing Electrode Layer>

It is preferred to form, as an opposing electrode layer 3, an ultrathin film made of platinum or carbon on a conducting substrate 2 because it is excellent in mobility of holes. In addition, an opposing electrode layer obtained by electrodepositing an ultrathin film made of gold (Au), palladium (Pd) or aluminum (Al) is exemplified. Also, a porous film made of fine particles of these materials, for example, a porous film made of carbon fine particles is preferred. Consequently, the surface area of the opposing electrode layer 3 increases and the electrolyte 4 can be contained in the pore section, thus making it possible to improve the conversion efficiency.

### <Porous Spacer Layer>

The porous spacer layer 5 is preferably a thin film made of a porous body obtained by sintering alumina fine particles. As shown in FIG. 4, the porous spacer layer 5 is formed on an opposing electrode layer 3.

Aluminium oxide (Al₂O₃) is most suited for use as the material or composition of the porous spacer layer 5, and the other material is preferably an insulating (electronic energy band gap is 3.5 eV or more) metal oxide such as silicon oxide (SiO₂). When the porous spacer layer is a collection of these granular bodies, acicular bodies, columnar bodies and/or the like, the porous spacer layer can contain the electrolyte solution, thus allowing improved conversion efficiency. The porous spacer layer 5 is preferably a porous body having porosity in the range from 20 to 80%, and more preferably from 40 to 60%. The mean particle size or the mean fiber diameter of the granular body, the acicular body and the columnar body, each constituting the porous spacer layer 5, are preferably in the range from 5 to 800 nm, and more preferably from 10 to 400 nm. This is because miniaturization of the mean particle size or the mean fiber diameter of the material is not possible for the lower limit of 5 nm or less, and the sintering temperature increases when the upper limit of 800 nm is exceeded.

When the porous spacer layer 5 is a porous body, the surface of the porous spacer layer 5 or the porous semiconductor layer 7 and the interface comprise an uneven face, bringing about a light confinement effect, thus making possible further improvement of the conversion efficiency.

The porous spacer layer 5 made of alumina is manufactured by the following procedure. First, acetylacetone is added to an Al₂O₃ fine powder and the mixture is kneaded with deionized water to prepare a paste of aluminum oxide stabilized with a surfactant. The paste thus prepared is applied on an opposing electrode layer 3 at a given rate using a doctor blade method or a bar coating method, and then subjected to a heat treatment in atmospheric air at 300 to 600° C., preferably at 400 to 500° C., for 10 to 60 minutes, preferably for 20 to 40 minutes to form a porous spacer layer 5.

The inorganic p-type metal oxide-semiconductor is preferably made of CoO, NiO, FeO, Bi₂O₃, MoO₂, Cr₂O₃, SrCu₂O₂ or CaO—Al₂O₃. Also, the inorganic p-type compound semiconductor is preferably made of MoS₂, CuI, CuInSe₂, Cu₂O, CuSCN, Cu₂S, CuInS₂, CuAlO, CuAlO₂, CuAlSe₂, CuGaO₂, CuGaS₂ or CuGaSe₂, each containing a monovalent copper, and is also preferably GaP, GaAs, Si, Ge, or SiC.

The low-temperature growth method of the porous spacer layer 5 is preferably an electrodeposition method, a cataphoretic electrodeposition method or a hydrothermal synthesis method. The thickness of the porous spacer layer 5 is in the range from 0.01 to 300 μm, and more preferably from 0.05 to 50 μm. The sintering temperature of fine particles constituting the porous spacer layer 5 is preferably higher than the sintering temperature of the porous semiconductor layer 7 and also the mean particle size of fine particles is preferably larger than the mean particle size of the porous semiconductor layer 7. In this case, electric resistance of the electrolyte 4 decreases, thus making it possible to improve the conversion efficiency.

The porous spacer layer 5 is formed for ensuring electric insulation between the porous semiconductor layer 7 and the opposing electrode layer 3. It is preferable that the porous spacer layer 5 has a thickness that is uniform and is as small as possible, and is porous so as to contain the electrolyte solution. When the oxidation-reduction reaction distance or the hole transportation distance decreases, the conversion efficiency is improved. Also, when the thickness of the porous spacer layer 5 becomes more uniform, a large-area photoelectric conversion device with high reliability can be realized.

### <Electrolyte>

The electrolyte 4 is particularly preferably a hole transporter (p-type semiconductor, liquid electrolyte, solid electrolyte, electrolytic salt, etc.) such as a gel electrolyte. The electrolyte 4 formed from a gel electrolyte is formed so as to fill a porous material. An electrolytic solution (liquid electrolyte) exhibits most preferred carrier transfer but causes a problem such as liquid leakage, and thus a highly-gelled or solidified one is preferred.

Examples of the material of the electrolyte 4 include a transparent conductive oxide, an electrolyte solution, an electrolyte such as a gel electrolyte or a solid electrolyte, an organic hole-transporting material and an ultrathin film metal. The transparent conductive oxide is preferably a compound semiconductor containing a monovalent copper, GaP, NiO, CoO, FeO, Bi₂O₃, MoO₂ or Cr₂O₃, of which a semiconductor containing a monovalent copper is preferred. The compound semiconductor suited for use in the present invention is preferably CuI, CuInSe₂, Cu₂O, CuSCN, CuS, CuInS₂ or CuAlSe₂, of which CuI and CuSCN are preferred and CuI is most preferred because it is easy to be manufactured.

When the electrolyte 4 is a liquid, a solution of a quaternary ammonium salt or a Li salt is used as an electrolyte solution. The electrolyte solution to be used can be prepared by mixing ethylene carbonate, acetonitrile or methoxypropionitrile with tetrapropylammonium iodide, lithium iodide or iodine.

The gel electrolyte is roughly classified into a chemical gel and a physical gel. Regarding the chemical gel, a gel is formed by a chemical bond through a crosslinking reaction, while a gel is formed at approximately room temperature through a physical interaction regarding the physical gel. The gel electrolyte is preferably a gel electrolyte obtained by mixing acetonitrile, ethylene carbonate, propylene carbonate or a mixture thereof with a host polymer such as polyethylene oxide, polyacrylonitrile, polyvinylidene fluoride, polyvinyl alcohol, polyacrylic acid or polyacrylamide and polymerizing the mixture. When the gel electrolyte or the solid electrolyte is used, it is possible to gel or solidify by mixing a precursor of low viscosity into oxide-semiconductor layer and a porous semiconductor layer and causing a two-dimensional or three-dimensional crosslinking reaction through means such as heating, ultraviolet irradiation or electron beam irradiation. When a gel electrolyte is used, gelation or solidification may be performed after injecting a solution before gelation into the laminated body 4.

The ion-conductive solid electrolyte is preferably a solid electrolyte including a salt such as a sulfone imidazolium salt, a tetracyanoquinodimethane salt or a dicyanoquinodiimine salt in polyethylene oxide or a polymer chain of polyethylene oxide or polyethylene. As the molten salt of iodide, for example, an iodide such as an imidazolium salt, a quaternary ammonium salt, an isooxazolidinium salt, an isothiazolidinum salt, a pyrazolidium salt, a pyrrolidinium salt or a pyridinium salt can be used.

Examples of the molten salt of the iodide include 1,1-dimethylimidazolium iodide, 1-methyl-3-ethylimidazolium iodide, 1-methyl-3-pentylimidazolium iodide, 1-methyl-3-isopentylimidazolium iodide, 1-methyl-3-hexylimidazolium iodide, 1-methyl-3-ethylimidazolium iodide, 1,2-dimethyl-3-propylimidazoleiodide, 1-ethyl-3-isopropylimidazolium iodide and pyrrolidinium iodide.

Examples of the organic hole-transporting material include triphenyldiamine (TPD1, TPD2, TPD3) and 2,2′,7,7′-tetrakis(N,N-di-p-methoxyphenylamine)9,9′-spirobifl uorene (OMeTAD).

### <Porous Semiconductor Layer>

The porous semiconductor layer 7 is particularly preferably an electron transporter (n-type metal oxide-semiconductor) such as a porous titanium dioxide.

As the porous semiconductor layer 7, an n-type metal oxide-semiconductor is commonly used, and is preferably a collection of granular bodies or fibrous bodies (acicular bodies, tubular bodies, columnar bodies, etc.).

When the porous semiconductor layer 7 is a porous body, the contacting surface area that causes a photoelectric conversion action increases and the surface area that adsorbs the dye 6 increases, thus allowing improved conversion efficiency.

Titanium oxide (TiO₂) is most suited for use as the material or composition of the metal oxide-semiconductor constituting the porous semiconductor layer 7, and the other material may be an oxide-semiconductor comprising at least one kind of metal element such as titanium (Ti), zinc (Zn), tin (Sn), niobium (Nb), indium (In), yttrium (Y), lanthanum (La), zirconium (Zr), tantalum (Ta), hafnium (Hf), strontium (Sr), barium (Ba), calcium (Ca) and vanadium (V). Also, the material may contain one or more kinds of non-metal elements such as nitrogen (N), carbon (C), fluorine (F), sulfur (S), chlorine (Cl) and phosphorus (P). It is preferred that each of them is n-type semiconductor which has an electronic energy band gap in the range from 2 to 5 eV that is larger than the energy of visible light and in which the conduction band is lower than that of the dye 6 in an electronic energy level.

It is preferable that this metal oxide-semiconductor is a porous body having a void fraction of 20% to 80%, and more preferably 40% to 60%. The reason is as follows. Porosity of the void fraction mentioned above allows the surface area of the porous semiconductor layer 7 to be improved by a factor of 1,000 or more as compared to that of a non-porous body, and thus good efficiency of optical sorption, electric generation and electronic conduction can be obtained. It is preferable that the shape of the porous semiconductor layer 7 is such that the surface area of the same is large and the electrical resistance is low, for example, that obtained by a composition of fine particles or a fine fibrous body. The mean particle size or the mean fiber diameter of the same is in the range from 5 to 500 nm, and more preferably from 10 to 200 nm. This is because miniaturization of the mean particle size or the mean fiber diameter of the material is not possible for the lower limit of 5 nm or less, and the contacting surface area becomes small and thus photocurrent becomes markedly low when the upper limit of 500 nm is exceeded.

The thickness of the porous semiconductor layer 7 is in the range from 0.1 to 50 μm, and more preferably from 1 to 20 μm. This is because the photoelectric converting action markedly decreases and practical use is not possible for the lower limit of 0.1 μm or less, and light does not permeate and light is not made incident when the upper limit of 50 μm is exceeded.

The titanium oxide-semiconductor constituting the porous semiconductor layer 7 is formed by the following procedure. First, acetylacetone is added to a TiO₂ anatase powder and the mixture is kneaded with deionized water to prepare a paste of titanium oxide stabilized with a surfactant. The paste thus prepared is applied on a porous spacer layer 5 at a given rate using a doctor blade method or a bar coating method and then subjected to a heat treatment in atmospheric air at 300 to 600° C., preferably at 400 to 500° C., for 10 to 60 minutes, preferably for 20 to 40 minutes to form a porous semiconductor layer 7.

The low-temperature growth method of the metal oxide-semiconductor is preferably an electrodeposition method, a cataphoretic electrodeposition method or a hydrothermal synthesis method, a microwave processing or a UV treatment may be preferred as a post-treatment. The material of the metal oxide-semiconductor is preferably porous ZnO formed by the electrodeposition method or porous TiO₂ formed by the cataphoretic electrodeposition method. The manufacturing method of the metal oxide-semiconductor made of titanium may be applied to the formation method of the porous light-transmitting coating layer 19.

### <Dye>

The dye 6 is effective when it is a dye 6 with characteristics in which photocurrent efficiency (IPCE: Incident Photon to Current Efficiency) to incident light extends to a side of a wavelength that is longer than an absorption limit wavelength (about 380 nm) of the metal oxide-semiconductor. Also, the dye 6 is effective when it is a dye 6 with characteristics in which photocurrent efficiency extends to a side of a wavelength that is longer than a substantially intrinsic amorphous silicone-based semiconductor.

The method of adsorbing the dye 6 to the metal oxide-semiconductor constituting the porous semiconductor layer 7 includes, for example, a method of immersing the conducting substrate 2, on which the porous semiconductor layer 7 is formed, in a solution containing the dye 6 dissolved therein. When the conducting substrate 2, on which the porous semiconductor layer 7 is formed, is immersed in the solution containing the dye 6 dissolved therein, the temperature of the solution and the atmosphere is not specifically limited and is, for example, room temperature under atmospheric pressure. The immersion time can be appropriately adjusted according to the kind of dye 6, the kind of solvent and the concentration of the solution. Consequently, the dye 6 can be adsorbed to the porous semiconductor layer 7.

As the solvent of the solution into which the dye 6 is dissolved, for example, alcohols such as ethanol; ketones such as acetone; ethers such as diethylether; and nitrogen compounds such as acetonitrile are used alone or a mixture of two or more kinds of them.

The concentration of the dye in the solution is preferably in the range from about 5×10⁻⁵ to 2×10⁻³ mol/l (liter: 1,000 cm³).

Other material of the dye 6 may be an inorganic dye, an inorganic pigment or an inorganic semiconductor, in addition to a metal complex dye, an organic dye or an organic pigment. Also, the shape of the dye 6 may be at least one kind of molecule, an ultrathin film, fine particles, ultrafine particles and a quantum dot. Particularly, in the case of an ultrafine particle semiconductor, a band gap is not a value peculiar to the material any longer and depends on the size. Even in the case of a material having a considerably small band gap (1 eV or less), the band gap can be increased by nanosization. Therefore, an adsorption wavelength can be selected and sensitivity can be easily shifted to a longer wavelength side. Examples of the material of the ultrafine particle semiconductor include CdS, CdSe, PbS, PbSe, CdTe, Bi₂S₃, InP and Si.

By immersing the conducting substrate 2 with the laminated body 41 formed thereon in the dye solution, the dye 6 solution is permeated into the laminated body 41 through the porous light-transmitting coating layer 19 and then the dye 6 is adsorbed on the porous semiconductor layer 7. In this case, a dye 6 solution is preferably stirred because the dye 6 is quickly adsorbed. The stirring rate (rotation number when a mag mixer is used) is preferably in the range from about 60 to 600 rpm in the case of a solution with a volume of 30 cc.

### <Light-Transmitting Conductive Layer>

As the light-transmitting conductive layer 8, a fluorine-doped tin dioxide film (SnO₂:F film) formed by a thermal CVD method or a spray pyrolysis deposition method may be most preferred, because it is formed at low cost and exhibits small sheet resistance. Also, a tin-doped indium oxide film (ITO film) formed by a sputtering method and an impurity-doped zinc oxide film (ZnO film) formed by a solution growth method may be used and these films may be laminated before use. An uneven face of a wavelength order of incident light is preferably formed upon film formation because a light confinement effect is obtained. In addition, an impurity-doped indium oxide film (In₂O₃ film) can be used. Also, these films can be formed by a dip coating method, a sol-gel method, a vacuum deposition method or an ion plating method.

It is possible to provide a plurality of through holes, that pass completely, in the light-transmitting conductive layer 8, and to permeate or inject the dye 6 solution and the electrolytic solution into the laminated body 41 through the through holes. The through holes, each having a diameter in the range from about several μm to several hundreds of μm, are preferably opened at an interval in the range of several mm□s (several mms×several mms) to several tens of mm□s (several tens of mms×several tens of mms) (□: square). When the size of the through holes is too small or the number is too small, it may become impossible to sufficiently adsorb the dye 6 solution and the electrolytic solution. In contrast, when the size of the through holes is too large or the number is too large, the cross-sectional area of the light-transmitting conductive layer 8, as a conductor through which current passes, decreases. Thus, it becomes impossible to supply sufficient electrons to the porous semiconductor layer 7 and the conversion efficiency may decrease. Therefore, the size and the number per unit area of the through holes are appropriately set to the values that prevent the above problems from occurring. These through holes may be formed by a known thin film formation technique or a known etching technique, for example, a method using a metal mask.

The light-transmitting conductive layer 8 may be a porous body in place of opening the through holes. For example, a porous light-transmitting conductive layer 8 may be formed by forming an organic silane solution comprising an organic silane containing ITO as a main component, waters an alcohol, an acid or an alkali, and a surfactant into a film using a spray coating method, and subjecting the film to a heat treatment.

### Third Embodiment

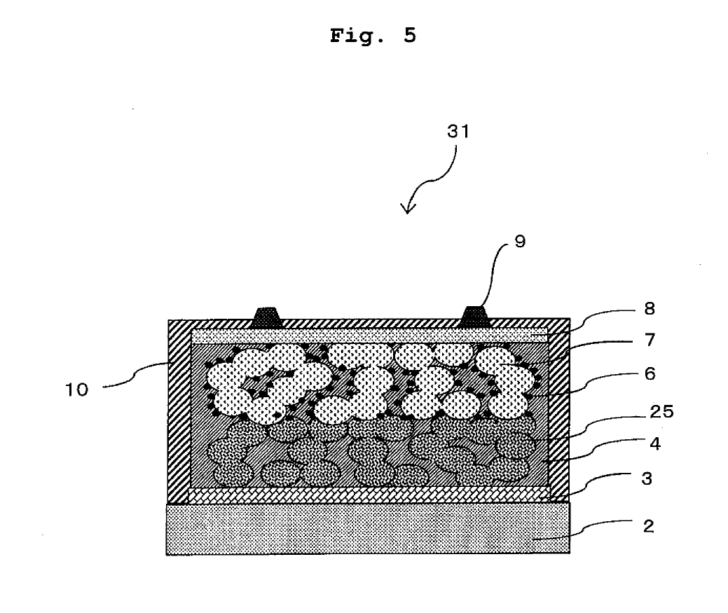

A schematic sectional view showing an example of a third embodiment according to a photoelectric conversion device of the present invention is shown in FIG. 5. The photoelectric conversion device 31 shown in FIG. 5 includes a laminated body including an opposing electrode layer 3, a permeation layer into which an electrolyte 4 solution permeates, the permeated solution being held by a surface tension, a porous semiconductor layer 7 that adsorbs (supports) a dye 6 and contains the electrolyte 4 and a light-transmitting conductive layer 8 respectively laminated in this order on the conducting substrate 2.

In the present invention, the electrolyte 4 may be a liquid, but may be a chemical gel that is a liquid phase body before permeation into the permeation layer 25 and is converted into a gel body after permeation. Phase change from the liquid body into the gel body of the chemical gel can be performed by heating.

In the manufacturing method of the photoelectric conversion device 31 shown in FIG. 5, on the conducting substrate 2, the opposing electrode layer 3, the permeation layer 25, the porous semiconductor layer 7 and the light-transmitting conductive layer 8 are laminated in this order to form a laminated body. Then, the laminated body is immersed in a dye 6 solution thereby adsorbing a dye 6 into the porous semiconductor layer 7 through the permeation layer 25, and the electrolyte 4 solution is permeated into the porous semiconductor layer 7 through the permeation layer 25.

In this case, when the dye 6 is adsorbed into the porous semiconductor layer 7, the dye 6 can be adsorbed into the porous semiconductor layer 7 through a side surface and the permeation layer 25 of the laminated body by immersing the laminated body in the dye 6 solution, and also the dye 6 can be adsorbed more easily and quickly. When the electrolyte 4 solution is permeated into the porous semiconductor layer 7, the electrolyte 4 solution can be permeated into the porous semiconductor layer 7 through a side surface and the permeation layer 25 of the laminated body, and also the electrolyte 4 solution can be permeated more easily and quickly.

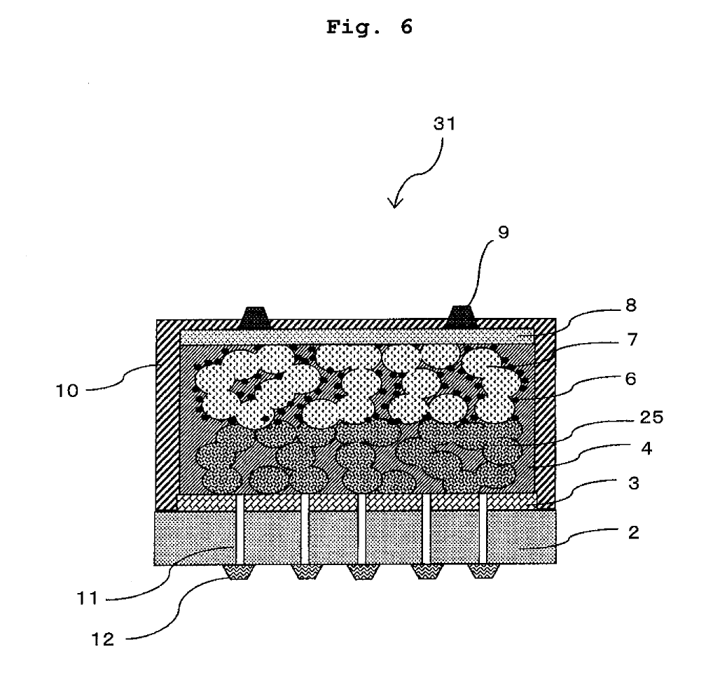

In this case, a plurality of through holes 11 (shown in FIG. 6) that pass completely through both the conducting substrate 2 and the opposing electrode layer 3 are opened and the electrolyte 4 solution is injected through the through holes 11, and then the electrolyte 4 solution is permeated into the porous semiconductor layer 7 through a side surface and the permeation layer 25 of the laminated body, and the through holes 11 are capped.

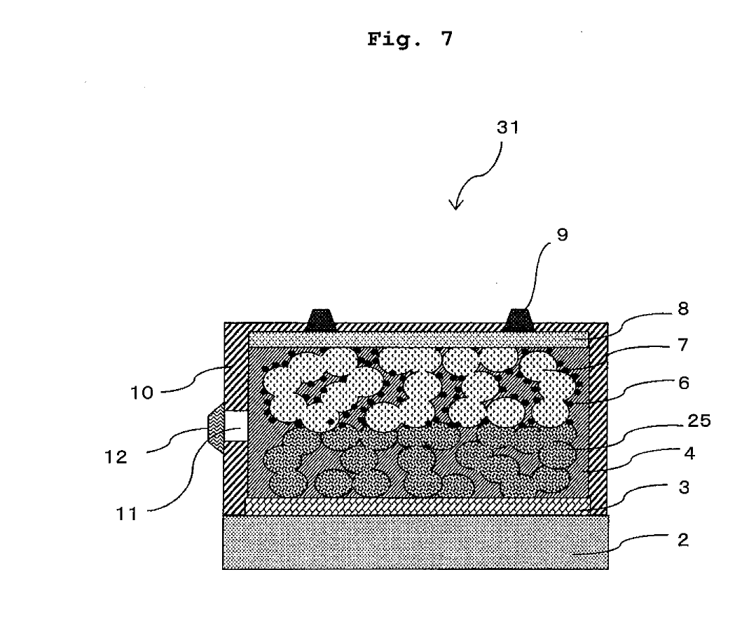

Alternatively, a plurality of through holes 11 (shown in FIG. 7) that pass completely through the light-transmitting sealing layer 10 are opened on the side surface of the laminated body and the electrolyte 4 solution is injected through the through holes 11, and then the electrolyte 4 solution is permeated into the porous semiconductor layer 7 through a side surface and the permeation layer 25 of the laminated body, and the through holes 11 are capped.

The light-transmitting sealing layer 10 shown in FIG. 5 to FIG. 7 comprises layered bodies such as a transparent resin layer, a glass layer formed by heating and solidifying a low melting point glass powder, and a sol-gel glass layer formed by curing a solution of a silicone alkoxide using a sol-gel method; tabular bodies such as a plastic plate and a glass plate; or foil-like bodies such as a thin metal film (sheet), or layered bodies, tabular bodies and foil-like bodies may be used in combination.

The permeation layer 25 of the present invention quickly absorbs and permeates the electrolyte 4 solution through a capillary phenomenon. Therefore, the electrolyte 4 solution can be quickly permeated into the entire permeation layer 25 and also the electrolyte 4 solution can be permeated to a side of the porous semiconductor layer 7 from a side of the permeation layer 25 of the porous semiconductor layer 7.

The respective elements constituting the photoelectric conversion device 31 described above are described in detail below.

### <Conducting Substrate>

As the conducting substrate 2, the same conducting substrate 2 as in the first embodiment can be used.

### <Opposing Electrode Layer>

As the opposing electrode layer 3, a catalyst layer and a conductive layer (not shown) are preferably laminated in this order from a side of the permeation layer 25.

The catalyst layer is preferably an ultrathin film having a catalyst function made of platinum or carbon. In addition, a film obtained by electrodeposition of an ultrathin film made of gold (Au), palladium (Pd) or aluminum (Al) is exemplified. When a porous film made of fine particles of these materials, for example, a porous film of carbon fine particles is used, the surface area of the opposing electrode layer 3 increases, thus making it possible to mix the electrolyte 4 into the pore section and to improve the conversion efficiency. The catalyst layer may be thin and can be made light-transmitting.

The conductive layer compensates conductivity of the catalyst layer. The conductive layer can be used in both non-light-transmitting and light-transmitting applications. The material of the non-light-transmitting conductive layer is preferably titanium, stainless steel, aluminum, silver, copper, gold, nickel or molybdenum. Also, the material may be a resin or conductive resin that contains fine particles or microfine fibers of carbon or metal. The material of a light reflective non-light-transmitting conductive layer is preferably a glossy thin metal film made of aluminum, silver, copper, nickel, titanium or stainless steel used alone, or a material in which a film comprising an impurity-doped metal oxide made of the same material as that of the light-transmitting conductive layer 8 is formed on a glossy metal thin film so as to prevent corrosion due to the electrolyte 4. Other conductive layers preferably comprise a multi-layered laminated body with improved adhesion, corrosion resistance and light reflectivity obtained by laminating a Ti layer, an Al layer and a Ti layer in this order. These conductive layers can be formed by a vacuum deposition method, an ion plating method, a sputtering method or an electrolytic deposition method.

The light-transmitting conductive layer preferably comprises a tin-doped indium oxide film (ITO film), an impurity-doped indium oxide film (In₂O₃ film), a impurity-doped tin oxide film (SnO₂ film) or an impurity-doped zinc oxide film (Zno film) formed by a low-temperature film growth sputtering method or a low-temperature spray pyrolysis deposition method. A fluorine-doped tin dioxide film (SnO₂: F film) formed by a thermal CVD method is preferred in view of low cost. Also, a laminated body with improved close adhesion obtained by laminating a Ti layer, an ITO layer and a Ti layer in this order is preferred. In addition, an impurity-doped zinc oxide film (ZnO film) formed by a simple solution growth method is preferred.

Examples of the other film formation method of these films include a vacuum deposition method, an ion plating method, a dip coating method and a sol-gel method. It is preferred to form an uneven face in a wavelength order of incident light by these film formation methods because a light confinement effect is obtained. The light-transmitting conductive layer may be an thin metal film with light-transmitting property, such as Au, Pd or Al formed by a vacuum deposition method or a sputtering method. The thickness of the light-transmitting conductive layer is preferably in the range from 0.001 to 10 μm, and more preferably from 0.05 to 2.0 μm, in view of high conductivity and high light transmittance. When the thickness is less than 0.001 μm, resistance of the conductive layer increases. In contrast, when the thickness exceeds 10 μm, light transmittance of the conductive layer deteriorates.

Here, when the opposing electrode layer 3 has light-transmitting property, light can be made incident from either of both faces of a principal surface of the photoelectric conversion device 31, and thus the conversion efficiency can be improved by making light to be incident from both faces of the principal surface.

### <Permeation Layer>

The permeation layer 25 is preferably a thin film made of a porous body obtained by sintering fine particles of aluminum oxide wherein the electrolyte 4 solution can be permeated through a capillary phenomenon and the solution is held by surface tension. As shown in FIG. 5, the permeation layer 25 is formed on the opposing electrode layer 3. The state where the electrolyte 4 solution is held by surface tension in the permeation layer 25 is a state of preventing leakage of the electrolyte 4 solution contained in the permeation layer 25 to the exterior, and the state can be easily discriminated by visual observation.

The arithmetic mean roughness of the surface or a fractured surface of the permeation layer 25 is preferably larger than the arithmetic mean roughness of the surface or a fractured surface of the porous semiconductor layer 7. Therefore, the mean particle size of fine particles constituting the permeation layer 25 is larger than that of the porous semiconductor layer 7. In this case, since the size of vacancies in the permeation layer 25 increases, a large amount of the electrolyte 4 can exist in the permeation layer 25 adjacent to the opposing electrode layer 3, and thus electric resistance of the electrolyte 4 contained in the permeation layer 25 decreases and the conversion efficiency can be improved.

The permeation layer 25 can maintain a gap between the porous semiconductor layer 7 and the opposing electrode layer 3 to be narrow and constant. Therefore, it is preferred that the permeation layer 25 has a thickness that is uniform and is as small as possible, and is porous so as to contain the dye 6 solution and the electrolyte 4 solution. As the thickness of the permeation layer 25 decreases, namely, the oxidation-reduction reaction distance or the hole transportation distance decreases, the conversion efficiency improves. Also, when the thickness of the permeation layer 25 becomes more uniform, a large-area photoelectric conversion device with high reliability can be realized.

The thickness of the permeation layer 25 is preferably in the range from 0.01 to 300 μm, and more preferably from 0.05 to 50 μm. When the thickness is less than 0.01 μm, the amount of the electrolyte 4 solution held by the permeation layer 25 decreases and thus electric resistance of the electrolyte 4 increases and the conversion efficiency is likely to deteriorate. In contrast, when the thickness exceeds 300 μm, a gap between the porous semiconductor layer 7 and the opposing electrode layer 3 increases and thus electric resistance due to the electrolyte 4 increases and the conversion efficiency is likely to deteriorate.

When the permeation layer 25 comprises insulator particles, the material is preferably Al₂O₃, SiO₂, ZrO₂, CaO, SrTiO₃ or BaTiO₃. Of these materials, Al₂O₃ is excellent in insulating properties for preventing short circuiting between the opposing electrode layer 3 and the porous semiconductor layer 7, and mechanical strength (hardness). Also, Al₂O₃ has a white color and therefore it does not absorb light with a specific color and preferably prevents deterioration of the conversion efficiency.

Also, when the permeation layer 25 comprises oxide-semiconductor particles, the material is preferably TiO₂, SnO₂, ZnO, CoO, NiO, FeO, Nb₂O₅, Bi₂O₃, MoO₂, Cr₂O₃, SrCu₂O₂, WO₃, La₂O₃, Ta₂O₅, CaO—Al₂O₃, In₂O₃, Cu₂O, CuAlO, CuAlO₂ or CuGaO₂, and MOS₂. Of these materials, TiO₂ adsorbs the dye 6 and can contribute to an improvement in the conversion efficiency. Also, TiO₂ is a semiconductor and thus it can suppress short circuiting between the opposing electrode layer 3 and the porous semiconductor layer 7 from occurring.

When the permeation layer 25 is a porous body comprising a collection of these granular bodies, acicular bodies, columnar bodies and/or the like, the electrolyte 4 solution can be contained, thus allowing improved conversion efficiency. The mean particle size or the mean fiber diameter of the granular body, the acicular body and the columnar body, each constituting the permeation layer 25, are preferably in the range from 5 to 800 nm, and more preferably from 10 to 400 nm. This is because miniaturization of the mean particle size or the mean fiber diameter of the material is not possible for the lower limit of 5 nm or less, and the sintering temperature increases when the upper limit of 800 nm is exceeded.

When the permeation layer 25 is a porous body, the surface of the permeation layer 25 or the porous semiconductor layer 7 and the interface comprise an uneven face, bringing about a light confinement effect, thus making possible further improvement of the conversion efficiency.

The low-temperature growth method of the permeation layer 25 is preferably an electrodeposition method, a cataphoretic electrodeposition method or a hydrothermal synthesis method.

Regarding the permeation layer 25, the arithmetic mean roughness (Ra) of the surface or the surface of a fractured surface is preferably 0.1 μm or more, more preferably from 0.1 to 0.5 μm, and still more preferably from 0.1 to 0.3 μm. When the arithmetic mean roughness (Ra) of the surface or the surface of a fractured surface of the permeation layer 25 is less than 0.1 μm, it becomes difficult to permeate the dye 6 solution or the electrolyte 4 solution into the permeation layer 25. In contrast, when the arithmetic mean roughness (Ra) of the surface or the surface of a fractured surface of the permeation layer 25 exceeds 0.5 μm, adhesion between the permeation layer 25 and the porous semiconductor layer 7 is likely to deteriorate. Furthermore, when Ra exceeds 1 μm, it becomes difficult to form the permeation layer 25. Here, Ra is defined in conformity to JXS-B-0601 and ISO-4287.

The arithmetic mean roughness (Ra) of the surface or the surface of a fractured surface of the permeation layer 25 approximately corresponds to the size of vacancies in the interior of the permeation layer 25 and the size of vacancies becomes approximately 0.1 μm when Ra is 0.1 μm.

Ra of the surface of the permeation layer 25 is measured by the following procedure. Using a probe type surface roughness tester, for example, SURFTEST (SJ-400) manufactured by Mitutoyo Corporation, the surface of the permeation layer 25 is measured. The method and the procedure of the measurement may be a method and a procedure for evaluation of a profile of the surface in conformity to JIS-B-0633 and ISO-4288. As the measuring position, a position with surface defects such as a scratch must be avoided. When the surface of the permeation layer 25 is isotropic, the measuring resistance, namely, the evaluation length, is appropriately set according to the value of Ra. For example, when Ra is more than 0.02 μm and is 0.1 μm or less, the evaluation length is set to 1.25 mm. In this case, the cut-off value for a roughness curve is set to 0.25 mm. The arithmetic mean roughness (Ra) of the surface or the surface of a fractured surface of the permeation layer 25 is measured in the same manner as in the case of the surface of the permeation layer 25. When the surface of a fractured surface of the permeation layer 25 is measured, an atomic force microscope or a laser microscope is preferably used for the following reason. Namely, the thickness of the permeation layer 25 is preferably in the range from 0.01 to 300 μm, and more preferably from 0.05 to 50 μm, and the fractured surface has a small width (film thickness), and thus the atomic force microscope (AFM) or laser microscope is suited for use as means capable of measuring in the range of several μm.

The permeation layer 25 is fractured by the following procedure. First, the surface opposite the opposing electrode layer 3 of the conducting substrate 2 is scratched using a dia cutter. The surface is scratched such that the scratch can be visually observed without causing generation of powders. Using pliers, a laminated body is fixed and the laminated body including the permeation layer 25 is fractured along the scratch formed on the conducting substrate 2.

Also, the scratched conducting substrate 2 may be fractured by the following procedure. First, a laminated body is placed on a block-shaped stand while facing the conducting substrate 2 upwardly. In this case, the laminated body is fixed in a state where the edge of the block-shaped stand is made to be parallel to the scratch formed on the conducting substrate 2 and also the scratch formed on the conducting substrate 2 is kept in air while being about 1 mm apart from the edge of the block-shaped stand. Then, a tabular jig with a width longer than that of the laminated body, for example, a stainless steel plate, is disposed on both sides of the scratch formed on the conducting substrate 2. The laminated body including the permeation layer 25 is fractured by downwardly pressing the jig kept on the portion kept in air of the laminated body while fixing the jig disposed on the portion of the laminated body on the block-shaped stand. Upon the fracturing of the permeation layer 25, the fractured surface preferably has a linear shape because it becomes easy to observe the fractured surface.

The permeation layer 25 is preferably a porous body with porosity in the range from 20 to 80%, and more preferably from 40 to 60%. When the porosity is less than 20%, it becomes difficult to permeate the dye 6 solution or the electrolyte 4 solution into the permeation layer 25. In contrast, when the porosity exceeds 80%, adhesion between the permeation layer 25 and the porous semiconductor layer 7 may deteriorate.

The porosity of the permeation layer 25 can be obtained by the following procedure. Using a gas adsorption measuring device, an isothermal adsorption curve of a sample is determined by a nitrogen gas adsorption method and the volume of vacancies is determined by a BJH (Barrett-Joyner-Halenda) method, a CI (Chemical Ionization) method or a DH (Dollimore-Heal) method, and then the porosity can be obtained from the resulting volume of vacancies and density of particles of the sample.

When the porosity of the permeation layer 25 is increased in the above range, the dye 6 solution is permeated more quickly and the dye 6 can be securely adsorbed into the porous semiconductor layer 7. Furthermore, resistance of the electrolyte 4 decreases, thus making it possible to further improve the conversion efficiency. In order to form the permeation layer 25 with large porosity, for example, a paste prepared by mixing fine particles (mean particle size: 31 nm) of aluminum oxide (Al₂O₃) with polyethylene glycol (molecular weight: about 20,000) is fired. In this case, a mixture prepared by mixing 70% by weight of fine particles (mean particle size: 31 nm) of aluminum oxide with 30% by weight of fine particles (mean particle size: 180 nm) having a larger mean particle size of titanium oxide (TiO₂) may be used. Larger porosity can also be obtained by adjusting the weight ratio, the mean particle size and the material.

In order to hold the electrolyte 4 solution permeated into the permeation layer 25 in the permeation layer 25 by surface tension, the size of vacancies of the permeation layer 25 is adjusted to a proper value according to the surface tension and density of the electrolyte 4 solution, or the contact angle between the electrolyte 4 solution and the permeation layer 25. For example, when the permeation layer 25 is formed by using an electrolyte 4 solution prepared by mixing ethylene carbonate, acetonitrile or methoxypropionitrile with tetrapropylammonium iodide, lithium iodide or iodine and using aluminum oxide or titanium oxide, the electrolyte 4 solution can be held in the permeation layer 25 when size of vacancies of the permeation layer 25 is adjusted to 1 μm or less.

The permeation layer 25 made of aluminum oxide is formed by the following procedure. First, acetylacetone is added to an Al₂O₃ fine powder and the mixture is kneaded with deionized water. After stabilizing with a surfactant, polyethylene glycol is added to a paste of aluminum oxide. The paste thus prepared is applied on an opposing electrode layer 3 at a given rate by a doctor blade method or a bar coating method, and then subjected to a heat treatment in atmospheric air at 300 to 600° C., preferably at 400 to 500° C., for 10 to 60 minutes, preferably for 20 to 40 minutes to form a permeation layer 25.

### <Porous Semiconductor Layer>

The porous semiconductor layer 7 is preferably a porous n-type oxide-semiconductor layer that comprises titanium dioxide and contains a large number of fine vacancies (size of vacancies is in the range from about 10 to 40 nm and a conversion efficiency shows a peak at 22 nm) therein. When the size of vacancies of the porous semiconductor layer 7 is less than 10 nm, immersion and adsorption of the dye 6 are inhibited and a sufficient adsorption amount of the dye 6 is not obtained. Also, diffusion of the electrolyte 4 is inhibited and diffusion resistance increases, thus deteriorating the conversion efficiency. When the size exceeds 40 nm, the specific surface area of the porous semiconductor layer 7 decreases. However, when the thickness must be increased so as to ensure the adsorption amount of the dye 6, it becomes hard to transmit light when the thickness is too large. Therefore, the dye 6 cannot absorb light and also the migration length of charges injected into the porous semiconductor layer 7 increases to cause large loss due to recombination of charges. Furthermore, diffusion length of the electrolyte 4 also increases and diffusion resistance increases, thus deteriorating the conversion efficiency.

As shown in FIG. 5, the porous semiconductor layer 7 is formed on the permeation layer 25. Titanium oxide (TiO₂) may be most suited for use as the material or composition of this porous body. Titanium oxide (TiO₂) is most suited for use as the material or composition of the porous semiconductor layer 7 and the other material is preferably a metal oxide-semiconductor made of at least one kind of metal element such as titanium (Ti), zinc (Zn), tin (Sn), niobium (Nb), indium (In), yttrium (Y), lanthanum (La), zirconium (Zr), tantalum (Ta), hafnium (Hf), strontium (Sr), barium (Ba), calcium (Ca), vanadium (V) and tungsten (W). Also, the material may contain one or more kinds of non-metal elements such as nitrogen (N), carbon (C), fluorine (F), sulfur (S), chlorine (Cl) and phosphorus (P). It is preferred that titanium oxide has an electronic energy band gap in the range from 2 to 5 eV that is larger than the energy of visible light. The porous semiconductor layer 7 is preferably an n-type semiconductor in which the conduction band is lower than that of the dye 6 in an electronic energy level.

The porous semiconductor layer 7 is a porous body comprising a granular body, a fibrous body such as an acicular body, a tubular body or a columnar body, or a collection of these various fibrous bodies, such that the surface area that adsorbs the dye 6 increases thus allowing improved conversion efficiency. It is preferable for the porous semiconductor layer 7 to be a porous body having a void fraction of 20% to 80%, and more preferably of 40% to 60%. The reason is as follows. Porosity allows the surface area of the photosensitive electrode layer to be improved by a factor of 1,000 or more as compared to that of a non-porous body, and thus good efficiency of optical sorption, photoelectric conversion and electronic conduction can be obtained.

The porosity of the porous semiconductor layer 7 can be obtained by the following procedure. An isothermal adsorption curve of a sample is determined by a nitrogen gas adsorption method using a gas adsorption measuring device and the volume of vacancies is determined by a BJH method, a CI method or a DH method, and then the porosity can be obtained from the resulting volume of vacancies and density of particles of the sample.

It is preferable that the shape of the porous semiconductor layer 7 is such that the surface area of the same is large and the electrical resistance is low, for example that obtained by a composition of fine particles or a fine fibrous body. The mean particle size or the mean fiber diameter of the same is in the range from 5 to 500 nm, and more preferably from 10 to 200 nm. This is because miniaturization of the mean particle size or the mean fiber diameter of the material is not possible for the lower limit of 5 nm or less, and the contacting surface area becomes small and thus photocurrent becomes markedly low when the upper limit of 500 nm is exceeded.

When the porous semiconductor layer 7 is a porous body, the surface of the dye-sensitized photoelectric converting body formed by adsorbing the dye 6 into the same becomes an uneven surface, bringing about a light confinement effect, thus making possible further improvement of the conversion efficiency.

The thickness of the porous semiconductor layer 7 is in the range from 0.1 to 50 μm, and more preferably from 1 to 20 μm. This is because the photoelectric converting action markedly decreases and practical use is not possible for the lower limit of 0.1 μm or less, and light does not permeate and light is not made incident when the upper limit of 50 μm is exceeded.

When the porous semiconductor layer 7 comprises titanium oxide, it is formed by the following procedure. First, acetylacetone is added to a TiO₂ anatase powder and the mixture is kneaded with deionized water to prepare a paste of titanium oxide stabilized with a surfactant. The paste thus prepared is applied on a permeation layer 25 at a given rate using a doctor blade method or a bar coating method and then subjected to a heat treatment in atmospheric air at 300 to 600° C., preferably at 400 to 500° C., for 10 to 60 minutes, preferably for 20 to 40 minutes to form a porous semiconductor layer 7. This technique is simple and preferable.

The low-temperature growth method of the porous semiconductor layer 7 is preferably an electrodeposition method, a cataphoretic electrodeposition method or a hydrothermal synthesis method. The porous semiconductor layer is preferably subjected to a microwave treatment, a plasma treatment using a CVD method, a thermal catalyst treatment or a UV irradiation treatment as a post-treatment for improving electronic transportation characteristics. The porous semiconductor layer 7 formed by the low-temperature growth method is preferably porous ZnO formed by the electrodeposition method or porous TiO₂ formed by the cataphoretic electrodeposition method.

The porous surface of the porous semiconductor layer 7 is preferably subjected to a TiCl₄ treatment, namely, a treatment of immersing in a TiCl₄ solution for 10 hours, washing with water and sintering at 450° C. for 30 minutes, because electron conductivity is improved, thus improving the conversion efficiency.

It is preferred that the porous semiconductor layer 7 comprises a sintered body of oxide-semiconductor fine particles and the mean particle size of oxide-semiconductor fine particles becomes progressively smaller progressing away from a side of the conducting substrate 2. For example, the porous semiconductor layer 7 preferably comprises a laminated body of two layers each having a different mean particle size of oxide-semiconductor fine particles. Specifically, oxide-semiconductor fine particles having a large mean particle size (scattered particles) is used at a side of the conducting substrate 2 and oxide-semiconductor fine particles having a small mean particle size is used at a side of the light-transmitting conductive layer 8, bringing about a light confinement effect of light scattering and light reflection in the porous semiconductor layer 7 at a side of the conducting substrate 2, thus making possible improvement of the conversion efficiency.

More specifically, it is preferred that 100% by weight of oxide-semiconductor fine particles having a mean particle size of about 20 nm are used as those having a small mean particle size and 70% by weight of oxide-semiconductor fine particles having a mean particle size of about 20 nm and 30% by weight of oxide-semiconductor fine particles having a mean particle size of about 180 nm are used in combination as those having a large mean particle size. An optimum light confinement effect is obtained by varying the weight ratio, the mean particle size and the film thickness. By increasing the number of layers from 2 to 3 or forming these layers so as not to produce a boundary between them, the mean particle size can become progressively smaller progressing away from a side of the conducting substrate 2.

### <Light-transmitting Conductive Layer>

As the light-transmitting conductive layer 8, a light-transmitting conductive layer S made of a metal oxide doped with fluorine or metal can be used. Of these layers, a fluorine-doped tin dioxide film (SnO₂: F film) formed by a thermal CVD method is preferred. A tin-doped indium oxide film (ITO film) and an impurity-doped indium oxide film (In₂O₃ film) formed by a low-temperature growth sputtering method and a low-temperature spray pyrolysis deposition method are preferred. In addition, an impurity-doped zinc oxide film (ZnO film) formed by a solution growth method is preferred. Also, these light-transmitting conductive layers 8 may be laminated in various combinations.

The thickness of the light-transmitting conductive layer 8 is in the range from 0.001 to 10 μm, and preferably from 0.05 to 2.0 μm, in view of high conductivity and high light transmittance. When the thickness is less than 0.001 μm, resistance of the light-transmitting conductive layer 8 increases. In contrast, when the thickness exceeds 10 μm, light transmittance of the light-transmitting conductive layer 8 deteriorates.

Examples of the other film formation method of the light-transmitting conductive layer 8 include a vacuum deposition method, an ion plating method, a dip coating method and a sol-gel method. By the growth of these films, the surface of the light-transmitting conductive layer 8 preferably comprises an uneven face in a wavelength order of incident light and more preferably brings about a light confinement effect.

The light-transmitting conductive layer 8 may be an ultrathin metal film made of Au, Pd, Al, Ti, Ni or stainless steel formed by a vacuum deposition method or a sputtering method.

### <Collecting Electrode>

The material of the collecting electrode 9 is obtained by applying a conductive paste comprising conductive particles made of silver, aluminum, nickel, copper, tin and carbon, an epoxy resin as an organic matrix, and a curing agent and firing the conductive paste. The conductive paste is particularly preferably an Ag paste or an Al paste, and both a low-temperature paste and a high-temperature paste can be used. A collecting electrode 9 formed from a metal-deposited film can be used by patterning of the film.

### <Light-Transmitting Sealing Layer>

In FIG. 5, the light-transmitting sealing layer 10 is provided so as to prevent leakage of an electrolyte 4 to the exterior, increase mechanical strength, protect a laminated body and prevent deterioration of photoelectric conversion function as a result of direct contact with an external environment.

The material of the light-transmitting sealing layer 10 is particularly preferably a fluororesin, a silicone polyester resin, a high-weatherability polyester resin, a polycarbonate resin, an acrylic resin, a PET (polyethylene terephthalate) resin, a polyvinyl chloride resin, an ethylene-vinyl acetate (EVA) copolymer resin, polyvinyl butyral (PVB), an ethylene-ethyl acrylate (EEA) copolymer, an epoxy resin, a saturated polyester resin, an amino resin, a phenol resin, a polyamideimide resin, a UV curing resin, a silicone resin, an urethane resin or a coating resin and an adhesive resin used for a metal roof because it is excellent in weatherability.

At least the light incidence surface of the light-transmitting sealing layer 10 is preferably light-transmitting. The thickness of the light-transmitting sealing layer 10 is in the range from 0.1 μm to 6 mm, and preferably from 1 μm to 4 mm, in view of high sealing properties and high light transmittance. When the thickness is less than 0.1 μm, sealing properties deteriorate. In contrast, when the thickness exceeds 6 mm, light transmittance of the light-transmitting sealing layer 10 deteriorates.

Also, by imparting antidazzle properties, heat shielding properties, heat resistance, low staining properties, antimicrobial, mildew resistance, design properties, high workability, scratching/abrasion resistance, snow slipperiness, antistatic properties, far-infrared radiation properties, acid resistance, corrosion resistance and environment adaptability to the light-transmitting sealing layer 10, reliability and merchantability can be more improved.

### <Dye>

The dye 6 as a sensitizing dye is preferably a ruthenium-tris, ruthenium-bis, osmium-tris or osmium-bis type transition metal complex, a multinuclear complex, a ruthenium-cis-diaqua-bipyridyl complex, phthalocyanine, porphyrin, a polycyclic aromatic compound, or a xanthene-based dye such as rhodamine B.

In order to adsorb the dye 6 to the porous semiconductor layer 7, it is effective that the dye 6 has at least one carboxyl group, sulfonyl group, hydroxamic acid group, alkoxy group, aryl group and phosphoryl group as a substituent. Herein, the substituent preferably enables strong chemical adsorption of the dye 6 itself to the porous semiconductor layer 7 and easy transfer of charges from the dye 6 in an excitation state to the porous semiconductor layer 7.

The method of adsorbing the dye 6 to the porous semiconductor layer 7 includes, for example, a method of immersing the porous semiconductor layer 7 formed on the permeation layer 25 in a solution containing the dye 6 dissolved therein.

In the manufacturing method of the present invention, a dye 6 is adsorbed to a porous semiconductor layer 7 during the process. Namely, an opposing electrode layer 3, a permeation layer 25, a porous semiconductor layer 7 and a light-transmitting conductive layer 8 are laminated in this order on a conducting substrate 2 to form a laminated body; the laminated body is immersed in a dye 6 solution such that the dye 6 is adsorbed into the porous semiconductor layer 7 through a side surface and the permeation layer 25 of the laminated body; and an electrolyte 4 is permeated into the porous semiconductor layer 7 through a side surface and the permeation layer 25 of the laminated body.

In this case, for example, a plurality of through holes 11 that pass completely through the conducting substrate 2 and the opposing electrode layer 3 are opened; a solution of an electrolyte 4 is injected through the through holes 11; the solution of the electrolyte 4 is permeated into the porous semiconductor layer 7 from a side surface of the laminated body and the permeation layer 25 of the laminated body; and the through holes 11 are capped. Alternatively, a plurality of through holes 11 pass completely through a light-transmitting sealing layer 10 on a side surface of the laminated body; a solution of an electrolyte 4 is injected through the through holes 11; the solution of the electrolyte 4 is permeated into the porous semiconductor layer 7 from the permeation layer 25; and the through holes 11 are capped.

As the solvent of the solution into which the dye 6 is dissolved, for example, alcohols such as ethanol; ketones such as acetone; ethers such as diethylether; and nitrogen compounds such as acetonitrile are used alone or a mixture of two or more kinds of them. The concentration of the dye 6 in the solution is preferably in the range from about 5×10⁻⁵ to 2×10⁻³ mol/l (liter: 1,000 cm³).

There are no restrictions on the solution and temperature conditions of the atmosphere in the case of immersing the conducting substrate 2 with the porous semiconductor layer 7 formed thereon in the solution containing the dye 6 dissolved therein. For example, the conducting substrate 2 is immersed in the solution under atmospheric pressure or a vacuum at room temperature or while heating. The immersion time can be appropriately controlled according to the kind of dye 6 and solution, and the concentration of the solution. Consequently, the dye 6 can be adsorbed to the porous semiconductor layer 7.

### <Electrolyte>

As the electrolyte 4, a quaternary ammonium salt or a Li salt is used. The electrolyte 4 solution to be used can be prepared by mixing ethylene carbonate, acetonitrile or methoxypropionitrile with tetrapropylammonium iodide, lithium iodide or iodine.

### <Photoelectric Power Generation Device>

Applications of the photoelectric conversion device 31 of the present invention are not limited to solar batteries. The photoelectric conversion device having a photoelectric conversion function can be utilized and can be applied to various photodetectors and optical sensors.

A photoelectric power generation device can be provided such that the above photoelectric conversion device 31 is utilized as means of electrical power generation, and the electrical power generated by the means of electrical power generation is supplied to a load. Namely, one photoelectric conversion device 31 described above is used or, when using a plurality of photoelectric conversion devices, those connected in series, in parallel or in serial-parallel are used as means of electrical power generation and electrical power may be directly supplied to a DC load from the means of electrical power generation. Also, there can be used an electrical power generation device capable of supplying the electrical power to a commercial power supply system or an AC load of various electrical equipment after converting means of photoelectrical power generation into a suitable AC electric power through electrical power conversion means such as an inverter. Furthermore, such an electrical power generation device can be utilized as a photoelectric power generation device of solar power generating systems of various aspects by building with a sunny aspect. Consequently, a photoelectric power generation device with high efficiency and durability can be provided.

The photoelectric conversion device of the present invention is described below by way of Examples and Comparative Examples, but the present invention is not limited only to the following Examples.

### EXAMPLE 1

Example 1 of the photoelectric conversion device of the present invention is described below. A photoelectric conversion device 1 with the constitution shown in FIG. 2 was manufactured by the following procedure.

First, as a conducting substrate 2, a titanium foil measuring 20 μm in thickness and 2 cm square was used. On the titanium foil, a platinum ultrathin film as an opposing electrode layer 3 was formed by a sputtering method.

Then, a porous spacer layer 5 made of aluminum was formed on the opposing electrode layer 3. The porous spacer layer 5 was formed by the following procedure. First, acetylacetone was added to an Al₂O₃ powder and the mixture was kneaded with deionized water to prepare an alumina paste stabilized with a surfactant. The paste thus prepared was applied on the conducting substrate 2 at a given rate using a doctor blade method and then fired in atmospheric air at 450° C. for 30 minutes.

Then, a porous semiconductor layer 7 made of titanium dioxide was formed on the conducting substrate 2. The porous semiconductor layer 7 was formed by the following procedure. First, acetylacetone was added to a TiO₂ anatase powder and the mixture was kneaded with deionized water to prepare a titanium oxide paste stabilized with a surfactant. The paste thus prepared was applied on the porous spacer layer 5 at a given rate using a doctor blade method and then fired in atmospheric air at 450° C. for 30 minutes.

On the porous semiconductor layer 7, an ITO film as a light-transmitting conductive layer 8 was deposited with a thickness of about 0.3 μm by a sputtering device using an ITO target while introducing Ar gas and O₂ gas (the content of O₂ gas is 10 volume %).

Furthermore, an Ag paste was applied on a portion of the ITO film and then heated to form a collecting electrode with a linear pattern.

Then, a sheet of a sealing material made of an olefinic resin was covered on the conducting substrate 2 and heated to form a light-transmitting sealing layer 10.

Then, a plurality of through holes 11 were formed on the back surface of the conducting substrate 2 by spot melting using a laser beam.

Then, the inside of the laminated body formed on the conducting substrate 2 was evacuated through the through holes 11 and then a dye 6 solution was injected into the laminated body through the through holes 11. As the dye 6 solution (the content of dye 6 is 0.3 mmol/l), a solution prepared by dissolving a dye 6 (“N719”, manufactured by Solaronix SA Co.) in acetonitrile and t-butanol (1:1 in terms of volume ratio) as a solvent was used.

The inside of the laminated body was evacuated through the through holes 11 and then an electrolytic solution was injected into the laminated body through the through holes 11. In Example 1, as an electrolyte 4, iodine (I₂) and lithium iodide (LiI) as the liquid electrolyte and an acetonitrile solution were used for preparation.

Regarding the photoelectric conversion device 1 of the present invention, photoelectric conversion characteristics were evaluated. The evaluation was performed by irradiation with light having a predetermined intensity and a predetermined wavelength and measuring photoelectric conversion efficiency (unit: %) that indicates electrical characteristics of the photoelectric conversion device. The electrical characteristics were measured by a method in conformity to JIS C 8913 using a solar simulator (WXS155S-10, manufactured by WACOM Co.).

As a result of the evaluation, it was found that photoelectric conversion efficiency is 2.8% at AM 1.5 and 100 mW/cm².

As described above, it could be confirmed that the photoelectric conversion device 1 of the present invention can be simply manufactured and also good conversion efficiency is obtained in Example 1.

### EXAMPLE 2

Example 2 of the photoelectric conversion device of the present invention is described below. A photoelectric conversion device 1 with the constitution shown in FIG. 3 was manufactured by the following procedure.

First, as a conducting substrate 2, a glass substrate (measuring 1 cm in length×2 cm in width) made of a fluorine-doped tin oxide, with a light-transmitting conductive layer, was used. On the glass substrate, a Pt layer as an opposing electrode layer 3 was formed in a thickness of 50 nm using a sputtering method.

On the opposing electrode layer 3, a porous spacer layer 5 made of alumina (Al₂O₃) fine particles (mean particle size: 31 nm) was formed. The porous spacer layer 5 was formed by the following procedure. First, acetylacetone was added to an Al₂O₃ powder and the mixture was kneaded with deionized water to prepare an alumina paste stabilized with a surfactant. The paste thus prepared was applied on the opposing electrode layer 3 at a given rate using a bar coating method and then fired in atmospheric air at 450° C. for 30 minutes to obtain a porous spacer layer 5 with a thickness of 12 μm.

Then, on the spacer layer 5, a porous semiconductor layer 7 made of titanium dioxide (TiO₂) fine particles (mean particle size: 25 nm) was formed to obtain a laminated body. The porous semiconductor layer 7 was formed by the following procedure. First, acetylacetone was added to a TiO₂ anatase powder and the mixture was kneaded with deionized water to prepare a titanium oxide paste stabilized with a surfactant. The paste thus prepared was applied on the glass substrate at a given rate using a bar coating method and then fired in atmospheric air at 450° C. for 30 minutes.

As the solvent in which a dye 6 (“N719”, manufactured by Solaronix SA Co.) is dissolved, acetonitrile and t-butanol (1:1 in volume ratio) were used. The glass substrate with the laminated body formed thereon was immersed in a solution containing the dye 6 dissolved therein (the content of dye 6 is 0.3 mmol/l) for 12 hours thereby adsorbing the dye 6 to the porous semiconductor layer 7. Then, the conducting substrate 2 was washed with ethanol and dried.

On the resulting porous semiconductor layer 7 containing the dye 6 adsorbed thereonto, an ITO film as a light-transmitting conductive layer 8 was deposited with a thickness of about 0.3 μm by a sputtering device using an ITO target while introducing Ar gas and O₂ gas (the content of O₂ gas is 10 volume %).

An Ag paste was applied on a portion of the ITO film and dried to form a collecting electrode 9 at a side of a photosensitive electrode, while a lead-free solder was soldered on a light-transmitting conductive layer made of a fluorine-doped tin oxide formed on the conducting substrate 2 using ultrasonic waves to form an electrode extracted from the opposing electrode layer 3.

Then, a sheet of a sealing material made of an olefinic resin was covered on the conducting substrate 2, followed by heating to form a light-transmitting sealing layer 10.

On a side of the light-transmitting sealing layer 10, the through holes 11 were formed by cutting a portion of the light-transmitting sealing layer 10 and an electrolyte 4 was injected from a side surface of the laminated body into the laminated body through the through holes 11. In Example 2, as the electrolyte 4, iodine (I₂) and lithium iodide (LiI) as the liquid electrolyte and an acetonitrile solution were used for preparation. The liquid electrolyte as an electrolytic solution was permeated into the laminated body from a side surface and then the through holes 11 were capped by the same sealing member 12 as that in the light-transmitting sealing layer 10.

Regarding the photoelectric conversion device 1 thus manufactured, photoelectric conversion characteristics were evaluated in the same manner as in Example 1. As a result, it was found that photoelectric conversion efficiency is 3.1% at AM 1.5 and 100 mW/cm².

As described above, it could be confirmed that the photoelectric conversion device 1 of the present invention can be simply manufactured and also good conversion efficiency is obtained in Example 2.

### EXAMPLE 3

Example 3 of the photoelectric conversion device of the present invention is described below. A photoelectric conversion device 1 with the constitution shown in FIG. 3 was manufactured by the following procedure.

First, as a conducting substrate 2, a titanium substrate (measuring 1 cm in length×2 cm in width) was used. On the titanium substrate, a Pt layer as an opposing electrode layer 3 was formed in a thickness of 50 nm by a sputtering method.

Then, on the opposing electrode layer 3, a porous spacer layer 5 made of alumina (Al₂O₃) fine particles (mean particle size: 31 nm) was formed. The porous spacer layer 5 was formed by the following procedure. First, acetylacetone was added to an Al₂O₃ powder and the mixture was kneaded with deionized water to prepare an alumina paste stabilized with a surfactant. The paste thus prepared was applied on the opposing electrode layer 3 at a given rate using a bar coating method and then fired in atmospheric air at 450° C. for 30 minutes to obtain a porous spacer layer 5 with a thickness of 12 μm.

Then, on the porous spacer layer 5 formed on the opposing electrode layer 3, a porous semiconductor layer 7 made of titanium dioxide (TiO₂) fine particles (mean particle size: 25 nm) was formed. The porous semiconductor layer 7 was formed by the following procedure. First, acetylacetone was added to a TiO₂ anatase powder and the mixture was kneaded with deionized water to prepare a titanium oxide paste stabilized with a surfactant. The paste thus prepared was applied on the porous spacer layer 5 formed on the titanium substrate at a given rate using a bar coating method and then fired in atmospheric air at 450° C. for 30 minutes.

On the porous semiconductor layer 7, an ITO film as a light-transmitting conductive layer 8 was accumulated in a thickness of about 0.3 μm by a sputtering device using an ITO target while introducing Ar gas and O₂ gas (the content of O₂ gas is 10 volume %) to obtain a laminated body.

As the solvent in which a dye 6 (“N719”, manufactured by Solaronix SA Co.) is dissolved, acetonitrile and t-butanol (1:1 in volume ratio) were used. The conducting substrate 2 with the laminated body formed thereon was immersed in a solution containing the dye 6 dissolved therein (the content of dye 6 is 0.3 mmol/l) for 12 hours thereby adsorbing the dye 6 to the porous semiconductor layer 7. Then, the conducting substrate 2 was washed with ethanol and dried.

Furthermore, an Ag paste was applied on a portion of the ITO film and then dried to form a collecting electrode 9 at a side of a photosensitive electrode, while the titanium substrate was used as an opposing electrode.

Then, a sheet of a sealing material made of an olefinic resin was covered on the conducting substrate 2 and heated to form a light-transmitting sealing layer 10.

On a side of the light-transmitting sealing layer 10, the through holes 11 were formed by cutting a portion of the light-transmitting sealing layer 10 and an electrolyte 4 was injected from a side surface of the laminated body into the laminated body through the through holes 11. In Example 3, as the electrolyte 4, iodine (I₂) and lithium iodide (LiI) as the liquid electrolyte and an acetonitrile solution were used for preparation. The electrolyte 4 as an electrolytic solution was permeated into the laminated body from a side surface and then the through holes 11 were capped by the same sealing member 12 as that in the light-transmitting sealing layer 10.

Regarding the photoelectric conversion device 1 thus manufactured, photoelectric conversion characteristics were evaluated in the same manner as in Example 1. As a result, it was found that photoelectric conversion efficiency is 3.0% at AM 1.5 and 100 mW/cm².

As described above, it could be confirmed that the photoelectric conversion device 1 of the present invention can be simply manufactured and also good conversion efficiency is obtained in Example 3.

### EXAMPLE 4

The photoelectric conversion device shown in FIG. 4 was manufactured by the following procedure. First, as a conducting substrate 2, a glass substrate (measuring 1 cm×2 cm) with a light-transmitting conductive layer made of a fluorine-doped tin oxide, was used. On the glass substrate, a Pt layer as an opposing electrode layer 3 was formed in a thickness of 50 nm by a sputtering method. Then, on the opposing electrode layer 3, a porous spacer layer 5 made of alumina (Al₂O₃) fine particles (mean particle size: 31 nm) was formed. The porous spacer layer 5 was formed by the following procedure. First, acetylacetone was added to an Al₂O₃ powder and the mixture was kneaded with deionized water to prepare an alumina paste stabilized with a surfactant. The paste thus prepared was applied on the opposing electrode layer 3 at a given rate using a bar coater method and then fired in atmospheric air at 450° C. for 30 minutes to obtain a porous spacer layer 5 with a thickness of 12 μm.

Then, on the porous spacer layer 5 formed on the opposing electrode layer 3, a porous semiconductor layer 7 made of titanium dioxide (TiO₂) fine particles (mean particle size: 25 nm) was formed. The porous semiconductor layer 7 was formed by the following procedure. First, acetylacetone was added to a TiO₂ anatase powder and the mixture was kneaded with deionized water to prepare a titanium oxide paste stabilized with a surfactant. The paste thus prepared was applied on the porous spacer layer 5 formed on the opposing electrode layer 3 at a given rate using a bar coating method and then fired in atmospheric air at 450° C. for 30 minutes.

On the porous semiconductor layer 7, an ITO film was accumulated in a thickness of about 0.3 μm by a sputtering device while introducing Ar gas and O₂ gas (Ar gas:O₂ gas=90 volume %:10 volume %), and then through holes with a diameter of about 0.1 mm were formed on a portion of the ITO film in a density of one hole per 1 mm² by etching to form a light-transmitting conductive layer 8.

Then, on the light-transmitting conductive layer 8, a porous SOG film (refractive index: about 1.52) made mainly of silicon dioxide (SiO₂) was formed as the light-transmitting coating layer 19. TEOS (tetraethoxysilane) was used as an organic silane for formation of the SOG film and nitric acid was used as an acid for hydrolysis. A solution of the organic silane was applied on the light-transmitting conductive layer 8, followed by vaporization of moisture in atmospheric air at about 200° C. and further firing at a temperature at about 350° C. under reduced pressure of about 1 Pa to obtain a porous SOG film.

The dye 6 solution was permeated into the porous semiconductor layer 7 from the light-transmitting conductive layer 8 and the light-transmitting coating layer 19 thereby adsorbing the dye 6 to the porous semiconductor layer 7. As the solvent in which a dye 6 (“N719”, manufactured by Solaronix SA Co.) is dissolved, acetonitrile and t-butanol (1:1 in volume ratio) were used. The conducting substrate 2 was immersed in a solution containing the dye 6 dissolved therein (0.3 mmol/l) for 12 hours thereby adsorbing the dye 6 to the porous semiconductor layer 7. Then, the conducting substrate 2 was washed with ethanol and dried.

The electrolytic solution (liquid electrolyte 4) was permeated into the porous semiconductor layer 7 from the light-transmitting conductive layer 8 and the light-transmitting coating layer 19. In Example 4, as the electrolytic solution, iodine (I₂) and lithium iodide (LiI) as the liquid electrolyte and an acetonitrile solution were used for preparation.

Finally, on the light-transmitting coating layer 19, a silicone resin layer (refractive index: about 1.49) with a thickness of about 10 μm was formed as the light-transmitting sealing layer 10 and the entire laminated body 41 formed on the conducting substrate 2 was sealed by covering with the silicone resin. A portion of the opposing electrode layer 3 and a portion of the light-transmitting conductive layer 8 were used as a terminal for extracting generated electric power to the exterior and the terminal section was exposed to the exterior of the light-transmitting coating layer 19.

Regarding the photoelectric conversion device thus manufactured, photoelectric conversion characteristics were evaluated in the same manner as in Example 1.

As a result of the evaluation, it was found that photoelectric conversion efficiency is 3.8% at AM 1.5 and 100 mW/cm².

As described above, the photoelectric conversion device of the present invention could be simply manufactured and also good conversion efficiency could be obtained in Example 4.

### EXAMPLE 5

A photoelectric conversion device shown in FIG. 5 was manufactured by the following procedure. First, as an insulating substrate, a commercially available soda glass plate substrate (measuring 3 cm in length and 2 cm in width) was used. On the insulating substrate, a Ti layer was deposited with a thickness of about 1 μm by a sputtering device using a Ti target so as to control sheet resistance to 0.5 Ω/□ (square) to form a metal layer, thus obtaining a conducting substrate 2.

On the conducting substrate 2, a platinum layer as an opposing electrode layer 3 was deposited with a thickness about 200 nm by a sputtering device using a Pt target to form an opposing electrode layer 3.

Then, on the opposing electrode layer 3, a permeation layer 25 made of an aluminum oxide was formed. The permeation layer 25 was formed by the following procedure. First, acetylacetone was added to an Al₂O₃ powder (mean particle size: 31 nm) and the mixture was kneaded with deionized water to prepare an aluminum oxide paste stabilized with a surfactant. The paste thus prepared was applied on an opposing electrode layer 3 at a given rate using a doctor blade method, and then subjected to a heat treatment in atmospheric air at 450° C. for 30 minutes. The arithmetic mean roughness of the surface of the permeation layer 25 was 0.221 μm. The arithmetic mean roughness of the surface of the permeation layer 25 was measured using a probe type surface roughness tester (“SURFTEST SJ-401”, manufactured by Mitutoyo Corporation). The arithmetic mean roughness of the surface was measured under the conditions of a measuring length of 4 mm and a cut-off value of 0.8 mm by a method in conformity to ISO-4288 using a Gauss-shaped filter.

Then, on the permeation layer 25, a porous semiconductor layer 7 made of titanium dioxide was formed. The porous semiconductor layer 7 was formed by the following procedure. First, acetylacetone was added to a TiO₂ anatase powder (mean particle size: 20 nm) and the mixture was kneaded with deionized water to prepare a titanium oxide paste stabilized with a surfactant. The paste thus prepared was applied on the permeation layer 25 at a given rate using a doctor blade method and then fired in atmospheric air at 450° C. for 30 minutes. The arithmetic mean roughness of the surface of the porous semiconductor layer 7 was 0.057 μm. The arithmetic mean roughness of the surface of the porous semiconductor layer 7 was measured using a probe type surface roughness tester (“SURFTEST SJ-401”, manufactured by Mitutoyo Corporation). The arithmetic mean roughness of the surface was measured under the conditions of a measuring length of 1.25 mm and a cut-off value of 0.25 mm by a method in conformity to ISO-4288 using a Gauss-shaped filter.

On the porous semiconductor layer 7, an ITO layer as a light-transmitting conductive layer 8 was deposited with a thickness of about 250 nm by a sputtering device using an ITO target so as to control sheet resistance to 5 Ω/□ (square) to form a light-transmitting conductive layer 8.

A portion of the laminated body was mechanically removed to expose a side surface of a permeation layer 25, and then the laminated body was immersed in a dye 6 solution for 39 hours thereby adsorbing the dye 6 to the porous semiconductor layer 7 through the permeation layer 25. A dye 6 solution (the content of dye 6 is 0.3 mmol/l) prepared by dissolving a dye 6 (“N719”, manufactured by Solaronix SA Co.) in acetonitrile and t-butanol (1:1 in terms of volume ratio) as a solvent was used.

Then, an Ag paste was applied to a portion of the conducting substrate 2 and heated to form an extract electrode (not shown). Furthermore, on a portion of the light-transmitting conductive layer 8, a solder was soldered using ultrasonic waves to form an extract electrode (collecting electrode 9).

Then, an electrolytic solution was permeated into the porous semiconductor layer 7 through the permeation layer 25. In Example 5, as the electrolyte 4, iodine (I₂) and lithium iodide (LiI) as a liquid electrolyte, and an acetonitrile solution were used for preparation. Then, a sheet made of an olefinic resin serving as a sealing member was covered on the laminated body, followed by heating to form a light-transmitting sealing layer 10 as a sealing member.

Regarding the photoelectric conversion device thus obtained, photoelectric conversion characteristics were evaluated in the same manner as in Example 1. As a result of the evaluation, it was found that photoelectric conversion efficiency is 4.4% at AM 1.5 and 100 mW/cm².

As described above, it could be confirmed that the photoelectric conversion device of the present invention can be simply manufactured and also good conversion efficiency is obtained in Example 5.

### EXAMPLE 6

A photoelectric conversion device shown in FIG. 6 was manufactured by the following procedure. First, as an insulating substrate, a commercially available soda glass plate substrate (measuring 3 cm in length and 2 cm in width) was used. On the insulating substrate, a Ti layer was deposited with a thickness of about 1 μm by a sputtering device using a Ti target so as to control sheet resistance to 0.5 Ω/□ (square) to form a metal layer, thus obtaining a conducting substrate 2. While rotating an electrodeposition diamond bar around an axis at high speed, the conducting substrate 2 was cut from the back surface of the conducting substrate 2 to form a plurality of through holes 11.

Then, on the conducting substrate 2, an opposing electrode layer 3 made of platinum was formed in the same manner as in Example 5.

On the opposing electrode layer 3, a permeation layer 25 made of aluminum oxide was formed in the same manner as in Example 5. The arithmetic mean roughness of the surface of the permeation layer 25 was 0.254 μm. The arithmetic mean roughness of the surface of the permeation layer 25 was measured using a probe type surface roughness tester (“SURFTEST SJ-401”, manufactured by Mitutoyo Corporation). The arithmetic mean roughness of the surface was measured under the conditions of a measuring length of 4 mm and a cut-off value of 0.8 mm by a method in conformity to ISO-4288 using a Gauss-shaped filter.

Then, on the permeation layer 25, a porous semiconductor layer 7 made of titanium dioxide was formed in the same manner as in Example 5. The arithmetic mean roughness of the surface of the porous semiconductor layer 7 was 0.058 μm. The arithmetic mean roughness of the surface of the porous semiconductor layer 7 was measured using a probe type surface roughness tester “SURFTEST SJ-401”, manufactured by Mitutoyo Corporation). The arithmetic mean roughness of the surface was measured under the conditions of a measuring length of 1.25 mm and a cut-off value of 0.25 mm by a method in conformity to ISO-4288 using a Gauss-shaped filter.

On the porous semiconductor layer 7, a light-transmitting conductive layer 8 made of ITO was formed in the same manner as in Example 5.

A portion of the laminated body was mechanically removed to expose a side surface of a permeation layer 25, and then the laminated body was immersed in the same dye 6 solution as in Example for 39 hours thereby adsorbing the dye 6 to the porous semiconductor layer 7 through the permeation layer 25.

Then, an Ag paste was applied to a portion of the conducting substrate 2 and heated to form an extract electrode (not shown). Furthermore, on a portion of the light-transmitting conductive layer 8, a solder was soldered using ultrasonic waves to form an extract electrode (collecting electrode 9).

Then, a sheet made of an olefinic resin serving as a sealing member was covered on the laminated body, followed by heating to form a light-transmitting sealing layer 10 as a sealing member.

The inside of the laminated body was evacuated through the through holes 11 formed on the conducting substrate 2, and then the same electrolytic solution as in Example 5 was injected into the laminated body through the through holes 11. Furthermore, the through holes 11 were capped by the same sealing member 12 (denoted by the reference numeral 12 in FIG. 6) as that in the light-transmitting sealing layer 10.

Regarding the photoelectric conversion device thus obtained, photoelectric conversion characteristics were evaluated in the same manner as in Example 1. As a result of the evaluation, it was found that photoelectric conversion efficiency is 5.0% at AM 1.5 and 100 mW/cm².

As described above, it could be confirmed that the photoelectric conversion device 1 of the present invention can be simply manufactured and also good conversion efficiency is obtained in Example 6.

### EXAMPLE 7

A photoelectric conversion device shown in FIG. 7 was manufactured by the following procedure. First, as an insulating substrate, a commercially available soda glass plate substrate (measuring 3 cm in length and 2 cm in width) was used. On the insulating substrate, a Ti layer was deposited with a thickness of about 1 μm by a sputtering device using a Ti target so as to control sheet resistance to 0.5 Ω/□ (square) to form a metal layer, thus obtaining a conducting substrate 2.

Then, on the conducting substrate 2, an opposing electrode layer 3 made of platinum was formed in the same manner as in Example 5.

On the opposing electrode layer 3, a permeation layer 25 made of titanium dioxide was formed. The permeation layer 25 was formed by the following procedure. First, acetylacetone was added to a mixed powder obtained by mixing two kinds of TiO₂ powders, a TiO₂ powder having a mean particle size of 20 nm and a TiO₂ powder having a mean particle size of 180 nm, in a mixing weight ratio of 10:2 and the mixture was kneaded with deionized water to prepare a titanium dioxide paste stabilized with a surfactant. The paste thus prepared was applied on an opposing electrode layer 3 at a given rate using a doctor blade method, and then subjected to a heat treatment in atmospheric air at 450° C. for 30 minutes. The arithmetic mean roughness of the surface of the permeation layer 25 was 0.157 μm. The arithmetic mean roughness of the surface of the permeation layer 25 was measured using a probe type surface roughness tester (“SURFTEST SJ-401”, manufactured by Mitutoyo Corporation). The arithmetic mean roughness of the surface was measured under the conditions of a measuring length of 4 mm and a cut-off value of 0.8 mm by a method in conformity to ISO-4288 using a Gauss-shaped filter.

Then, on the permeation layer 25, a porous semiconductor layer 7 made of titanium dioxide was formed in the same manner as in Example 5. The arithmetic mean roughness of the surface of the porous semiconductor layer 7 was 0.056 μm. The arithmetic mean roughness of the surface of the porous semiconductor layer 7 was measured using a probe type surface roughness tester (“SURFTEST SJ-401”, manufactured by Mitutoyo Corporation). The arithmetic mean roughness of the surface was measured under the conditions of a measuring length of 1.25 mm and a cut-off value of 0.25 mm by a method in conformity to ISO-4288 using a Gauss-shaped filter.

On the porous semiconductor layer 7, an ITO layer as a light-transmitting conductive layer 8 was deposited with a thickness of about 250 nm by a sputtering device using an ITO target so as to control sheet resistance to 0.5 Ω/□ (square) to form a light-transmitting conductive layer 8.

A portion of the laminated body was mechanically removed to expose a side surface of a permeation layer 25, and then the laminated body was immersed in the same dye 6 solution as in Example 5 for 39 hours thereby adsorbing the dye 6 to the porous semiconductor layer 7 through the permeation layer 25.

Then, an Ag paste was applied to a portion of the conducting substrate 2 and heated to form an extract electrode (not shown)

Furthermore, on a portion of the light-transmitting conductive layer 8, a solder was soldered using ultrasonic waves to form an extract electrode (collecting electrode 9).

Then, a sheet made of an olefinic resin serving as a sealing member was covered on the laminated body, followed by heating to form a light-transmitting sealing layer 10 as a sealing member. Furthermore, the through holes 11 were formed by cutting a portion of a side of the light-transmitting sealing layer 10 using a cutter. The inside of the laminated body was evacuated through the through holes 11, and then the same electrolytic solution as in Example 5 was injected into the laminated body through the through holes 11. The electrolytic solution was permeated into the porous semiconductor layer 7 through the permeation layer 25. Furthermore, the through holes 11 were capped by the same sealing member (denoted by the reference numeral 12 in FIG. 7) as that in the light-transmitting sealing layer 10.

Regarding the photoelectric conversion device 31 thus obtained, photoelectric conversion characteristics were evaluated in the same manner as in Example 1. As a result of the evaluation, it was found that photoelectric conversion efficiency is 4.6% at AM 1.5 and 100 mW/cm².

As described above, it could be confirmed that the photoelectric conversion device of the present invention can be simply manufactured and also good conversion efficiency is obtained in Example 7.

### COMPARATIVE EXAMPLE 1

As an insulating substrate, a commercially available soda glass plate substrate (measuring 3 cm in length and 2 cm in width) was used. On the insulating substrate, a Ti layer was deposited with a thickness of about 1 μm by a sputtering device using a Ti target so as to control sheet resistance to 0.5 Ω/□ (square) to form a metal layer, thus obtaining a conducting substrate 2.

Then, on the conducting substrate 2, an opposing electrode layer 3 made of platinum was formed in the same manner as in Example 5.

On the opposing electrode layer 3, a permeation layer 25 made of titanium dioxide was formed. The permeation layer 25 was formed by the following procedure. First, acetylacetone was added to a TiO₂ powder (mean particle size: 20 nm) and the mixture was kneaded with deionized water to prepare a titanium dioxide paste stabilized with a surfactant. The paste thus prepared was applied on the opposing electrode layer 3 at a given rate using a doctor blade method, and then subjected to a heat treatment in atmospheric air at 450° C. for 30 minutes. The arithmetic mean roughness of the surface of the permeation layer 25 was 0.057 μm. The arithmetic mean roughness of the surface of the permeation layer 25 was measured using a probe type surface roughness tester (“SURFTEST SJ-401”, manufactured by Mitutoyo Corporation). The arithmetic mean roughness of the surface was measured under the conditions of a measuring length of 1.25 mm and a cut-off value of 0.25 mm by a method in conformity to ISO-4288 using a Gauss-shaped filter.

Then, on the permeation layer 25, a porous semiconductor layer 7 made of titanium dioxide was formed in the same manner as in Example 5. The arithmetic mean roughness of the surface of the porous semiconductor layer 7 was 0.060 μm. The arithmetic mean roughness of the surface of the porous semiconductor layer 7 was measured using a probe type surface roughness tester (“SURFTEST SJ-401”, manufactured by Mitutoyo Corporation). The arithmetic mean roughness of the surface was measured under the conditions of a measuring length of 1.25 mm and a cut-off value of 0.25 mm by a method in conformity to ISO-4288 using a Gauss-shaped filter.

On the porous semiconductor layer 7, an ITO layer as a light-transmitting conductive layer 8 was deposited with a thickness of about 250 nm by a sputtering device using an ITO target so as to control sheet resistance to 5 Ω/□ (square) to form a light-transmitting conductive layer 8.

A portion of the laminated body was mechanically removed to expose a side surface of a permeation layer 25, and then the laminated body was immersed in the same dye 6 solution as in Example 5 for 39 hours. However, the dye 6 was not sufficiently adsorbed to the porous semiconductor layer 7. Then, the immersion time in the dye 6 solution was extended to 133 hours. However, the dye 6 was not sufficiently adsorbed to the porous semiconductor layer 7.

As described above, in Comparative Example 1, since the arithmetic mean roughness of the surface of the permeation layer 25 was smaller than that of the surface of the porous semiconductor layer 7, the size of vacancies of the permeation layer 25 decreased. Therefore, the dye 6 could not be sufficiently adsorbed to the porous semiconductor layer 7 through the permeation layer 25 and thus a photoelectric conversion device capable of attaining high conversion efficiency could not be obtained.

It was found that, when the surface Ra of the permeation layer 25 is less than 0.1 μm, it is difficult to permeate an electrolytic solution and also a very long time is required to adsorb the dye 6, and thus manufacturing of a photoelectric conversion device is inhibited.

### COMPARATIVE EXAMPLE 2

As an insulating substrate, a commercially available soda glass plate substrate (measuring 3 cm in length and 2 cm in width) was used. On the insulating substrate, a Ti layer was deposited with a thickness of about 1 μm by a sputtering device using a Ti target so as to control sheet resistance to 0.5 Ω/□ (square) to form a metal layer, thus obtaining a conducting substrate 2.

Then, on the conducting substrate 2, an opposing electrode layer 3 made of platinum was formed in the same manner as in Example 5.

On the opposing electrode layer 3, a permeation layer 25 made of titanium dioxide was formed. First, ethyl cellulose was added to TiO₂ obtained by hydrothermal synthesis and the mixture was kneaded with a terpineol solvent to prepare a titanium dioxide paste stabilized with a surfactant. The paste thus prepared was applied on the opposing electrode layer 3 at a given rate using a screen printing method, and then fired in atmospheric air at 450° C. for 30 minutes. The arithmetic mean roughness of the surface of the permeation layer 25 was 0.556 μm. The arithmetic mean roughness of the surface of the permeation layer 25 was measured using a probe type surface roughness tester (“SURFTEST SJ-401”, manufactured by Mitutoyo Corporation). The arithmetic mean roughness of the surface was measured under the conditions of a measuring length of 4 mm and a cut-off value of 0.8 mm by a method in conformity to ISO-4288 using a Gauss-shaped filter.

Then, on the permeation layer 25, a porous semiconductor layer 7 made of titanium dioxide was formed in the same manner as in Example 5. The arithmetic mean roughness of the surface of the porous semiconductor layer 7 was 0.057 μm. The arithmetic mean roughness of the surface of the porous semiconductor layer 7 was measured using a probe type surface roughness tester (“SURFTEST SJ-401”, manufactured by Mitutoyo Corporation). The arithmetic mean roughness of the surface was measured under the conditions of a measuring length of 1.25 mm and a cut-off value of 0.25 mm by a method in conformity to ISO-4288 using a Gauss-shaped filter.

On the porous semiconductor layer 7, an ITO layer as a light-transmitting conductive layer 8 was deposited with a thickness of about 250 nm by a sputtering device using an ITO target so as to control sheet resistance to 5 Ω/□ (square) to form a light-transmitting conductive layer 8.

A portion of the laminated body was mechanically removed to expose a side surface of a permeation layer 25, and then the laminated body was immersed in the same dye 6 solution as in Example 5. However, partial peeling occurred because of insufficient adhesion between the permeation layer 25 and the porous semiconductor layer 7.

As described above, in Comparative Example 2, since the arithmetic mean roughness of the surface of the permeation layer 25 exceeds 0.5 μm, adhesion between the permeation layer 25 and the porous semiconductor layer 7 is insufficient, and thus a photoelectric conversion device capable of attaining high conversion efficiency could not be obtained.

1. A photoelectric conversion device, comprising: a conducting substrate; an opposing electrode layer formed on the conducting substrate; a porous spacer layer containing an electrolyte and formed on the opposing electrode layer; a porous semiconductor layer that adsorbs a dye and contains the electrolyte, and is formed on the porous spacer layer; and a light-transmitting conductive layer formed on the semiconductor layer.

2. The photoelectric conversion device according to claim 1, wherein a light-transmitting sealing layer is formed such that an upper surface and a side surface of a laminated body are covered and the electrolyte is sealed therein, and the laminated body comprising the opposing electrode layer, the porous spacer layer, the semiconductor layer and the light-transmitting conductive layer respectively laminated in this order on the conducting substrate.

3. The photoelectric conversion device according to claim 1, wherein the semiconductor layer comprises a sintered body of oxide-semiconductor fine particles and the mean particle size of the oxide-semiconductor fine particles becomes progressively smaller in the thickness direction progressing away from a side of the conducting substrate.

4. The photoelectric conversion device according to claim 1, wherein the porous spacer layer is a porous body comprising fine particles of an insulator or a p-type semiconductor.

5. The photoelectric conversion device according to claim 1, wherein an interface between the porous spacer layer and the semiconductor layer comprises an uneven face.

6. The photoelectric conversion device according to claim 1, wherein the opposing electrode layer comprises a porous body containing the electrolyte.

7. A method of manufacturing a photoelectric conversion device, comprising the steps of: laminating an opposing electrode layer, a porous spacer layer, a porous semiconductor layer and a light-transmitting conductive layer in this order on a conducting substrate to form a laminated body; opening a plurality of through holes that pass completely through the conducting substrate and the opposing electrode layer; injecting a dye through the through holes such that the dye is adsorbed into the semiconductor layer; injecting an electrolyte into the interior of the laminated body; and capping of the through holes.

8. A method of manufacturing a photoelectric conversion device, comprising the steps of: laminating an opposing electrode layer, a porous spacer layer and a porous semiconductor layer in this order on a conducting substrate to form a laminated body; immersing the laminated body in a dye solution such that the dye is adsorbed into the semiconductor layer; forming a light-transmitting conductive layer laminated on the semiconductor layer; and finally permeating an electrolyte into the porous spacer layer and the semiconductor layer from at least a side surface of the laminated body.

9. A method of manufacturing a photoelectric conversion device, comprising the steps of: laminating an opposing electrode layer, a porous spacer layer, a porous semiconductor layer and a light-transmitting conductive layer in this order on a conducting substrate to form a laminated body; immersing the laminated body in a dye solution such that the dye is adsorbed into the semiconductor layer from a side surface of the laminated body; and finally permeating an electrolyte into the porous spacer layer and the semiconductor layer from at least a side surface of the laminated body.

10. The photoelectric conversion device according to claim 1, comprising: a porous light-transmitting coating into which allows permeation of the dye and that covers a side surface and an upper surface of a laminated body that comprises the opposing electrode layer, the porous spacer layer, the semiconductor layer and the light-transmitting conductive layer laminated in this order on the conducting substrate; and a light-transmitting sealing layer that covers and seals the surface of the light-transmitting coating.

11. The photoelectric conversion device according to claim 10, wherein the light-transmitting coating layer has vacancies of a size that prevents leakage from the surface to an exterior due to surface tension of an electrolyte solution.

12. The photoelectric conversion device according to claim 10, wherein the thickness of the light-transmitting coating layer is more than that of the light-transmitting sealing layer.

13. A method of manufacturing a photoelectric conversion device, comprising the steps of: laminating an opposing electrode layer, a porous spacer layer, a porous semiconductor layer and a light-transmitting conductive layer in this order on a conducting substrate to form a laminated body; forming a porous light-transmitting coating that covers a side surface and an upper surface of the laminated body; permeating a dye through the light-transmitting coating from an exterior into the semiconductor layer; injecting an electrolyte solution through the light-transmitting coating layer from an exterior into an interior of the light-transmitting coating layer; and finally covering the surface of the light-transmitting coating layer with a light-transmitting sealing layer.

14. A method of manufacturing a photoelectric conversion device according to claim 13, wherein the laminated body and the conducting substrate comprising the light-transmitting coating layer are immersed in a solution containing a dye when permeating the dye from an exterior through the light-transmitting coating layer into the semiconductor layer.

15. A method of manufacturing a photoelectric conversion device according to claim 14, wherein a solution containing the dye is stirred.

16. The photoelectric conversion device according to claim 1, wherein the porous spacer layer is a permeation layer into which an electrolyte solution permeates and inside which the permeated solution is contained.

17. The photoelectric conversion device according to claim 16, wherein the arithmetic mean roughness of the surface or a fractured surface of the permeation layer is larger than the arithmetic mean roughness of the surface or a fractured surface of the semiconductor layer.

18. The photoelectric conversion device according to claim 16, wherein the arithmetic mean roughness of the surface or a fractured surface of the permeation layer is in the range from 0.1 to 0.5 μm.

19. The photoelectric conversion device according to claim 16, wherein the permeation layer comprises a sintered body formed by sintering at least one type of particle selected from an insulator and an oxide semiconductor.

20. The photoelectric conversion device according to claim 16, wherein the permeation layer comprises a sintered body formed by sintering at least one of an aluminum oxide particle and a titanium oxide particle.

21. The photoelectric conversion device according to claim 16, comprising a light-transmitting sealing layer that seals the electrolyte by covering an upper surface and a side surface of the laminated body.

22. A method of manufacturing a photoelectric conversion device, comprising the steps of: laminating an opposing electrode layer, a permeation layer into which an electrolyte solution permeates and inside which the solution is contained, a porous semiconductor layer and a light-transmitting conductive layer in this order on a conducting substrate to form a laminated body; immersing the laminated body in a dye solution, wherein the dye is adsorbed into the semiconductor layer through the permeation layer; and finally permeating the electrolyte solution through the permeation layer into the semiconductor layer.

23. A photoelectric power generation device, provided such that the photoelectric conversion device according to claim 1 is utilized as means of electrical power generation, and the electrical power generated by the means of electrical power generation is supplied to a load.
